(19) United States
(12) Patent Application Publication
(10) Pub. No.: US 2025/0343176 A1
(43) Pub. Date: Nov. 6, 2025

(54) PACKAGE COMPRISING AN INTERPOSER PACKAGE WITH METALLIZATION PORTIONS, AND A PASSIVE DEVICE AND A BRIDGE BETWEEN THE METALLIZATION PORTIONS

(71) Applicant: QUALCOMM Incorporated, San Diego, CA (US)

(72) Inventors: Yanmei SONG, San Diego, CA (US); William STONE, San Diego, CA (US); Ryan LANE, San Diego, CA (US)

(21) Appl. No.: 18/655,027

(22) Filed: May 3, 2024

(51) Int. Cl. H01L 23/64; H01L 23/00; H01L 23/31; H01L 23/498; H01L 23/538; H01L 25/16; H10B 80/00

(52) U.S. Cl. CPC H01L 23/642; H01L 23/3135; H01L 23/49822; H01L 23/49838; H01L 23/5386; H01L 24/13; H01L 24/16; H01L 25/16; H10B 80/00; H01L 2224/1357; H01L 2224/16227; H01L 2224/16238; H01L 2924/19011; H01L 2924/19041

(57) ABSTRACT

A package comprising a first integrated device; a second integrated device; and a package interposer coupled to the first integrated device and the second integrated device. The package interposer comprises a first metallization portion; a second metallization portion; a first encapsulation layer coupled to the first metallization portion and the second metallization portion; and a passive device located at least partially in the first encapsulation layer. The first encapsulation layer and the passive device are located between the first metallization portion and the second metallization portion.

### FIELD

Various features relate to packages with interposers and integrated devices.

### BACKGROUND

A package may include a substrate, an interposer and/or integrated devices. These components are coupled together to provide a package that may perform various electrical functions. There is an ongoing need to provide better performing packages. Moreover, there is also an ongoing need to reduce the overall size of the packages.

### SUMMARY

Various features relate to packages with interposers and integrated devices.

One example provides a package comprising a first integrated device; a second integrated device; and a package interposer coupled to the first integrated device and the second integrated device. The package interposer comprises a first metallization portion; a second metallization portion; a first encapsulation layer coupled to the first metallization portion and the second metallization portion; and a passive device located at least partially in the first encapsulation layer. The first encapsulation layer and the passive device are located between the first metallization portion and the second metallization portion.

Another example provides a device comprising a package. The package comprises a first integrated device; a second integrated device; and a package interposer coupled to the first integrated device and the second integrated device. The package interposer comprises a first metallization portion; a second metallization portion; a first encapsulation layer coupled to the first metallization portion and the second metallization portion; and a passive device located at least partially in the first encapsulation layer. The first encapsulation layer and the passive device are located between the first metallization portion and the second metallization portion.

Another example provides a package comprising a first integrated device; a second integrated device; and a package interposer coupled to the first integrated device and the second integrated device. The package interposer comprises a first metallization portion; a second metallization portion; a first encapsulation layer coupled to the first metallization portion and the second metallization portion; and a bridge located at least partially in the first encapsulation layer. The first encapsulation layer and the bridge are located between the first metallization portion and the second metallization portion.

Another example provides a device comprising a package. The package comprises a first integrated device; a second integrated device; and a package interposer coupled to the first integrated device and the second integrated device. The package interposer comprises a first metallization portion; a second metallization portion; a first encapsulation layer coupled to the first metallization portion and the second metallization portion; and a bridge located at least partially in the first encapsulation layer. The first encapsulation layer and the bridge are located between the first metallization portion and the second metallization portion.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes at least one integrated device, a package interposer comprising a passive device and a bridge located at least partially in the package interposer.

FIG. 2 illustrates an exemplary cross sectional profile view of a package that includes at least one integrated device, a package interposer comprising a passive device and a bridge located at least partially in the package interposer.

FIG. 3 illustrates an exemplary cross sectional profile view of a package that includes at least one integrated device, a package interposer comprising a passive device and a bridge located at least partially in the package interposer.

FIG. 4 illustrates an exemplary cross sectional profile view of a package that includes at least one integrated device, a package interposer comprising a passive device and a bridge located at least partially in the package interposer.

FIG. 5 illustrates an exemplary cross sectional profile view of a package that includes at least one integrated device, a package interposer comprising a passive device and a bridge located at least partially in the package interposer.

FIG. 6 illustrates an exemplary plan view of a package that includes at least one integrated device, a package interposer comprising a passive device and a bridge located at least partially in the package interposer.

FIG. 7 illustrates an exemplary plan view of a package that includes at least one integrated device, a package interposer comprising a passive device and a bridge located at least partially in the package interposer.

FIG. 8 illustrates an exemplary plan view of a package that includes at least one integrated device, a package interposer comprising a passive device and a bridge located at least partially in the package interposer.

FIG. 9 illustrates an exemplary plan view of a package that includes at least one integrated device, a package interposer comprising a passive device and a bridge located at least partially in the package interposer.

FIG. 10 illustrates an exemplary profile view of a deep trench capacitor device.

FIG. 11 illustrates an exemplary profile view of a deep trench capacitor device comprising a through substrate via.

FIGS. 12A-12E illustrate an exemplary sequence for fabricating a package that includes at least one integrated device, a package interposer comprising a passive device and a bridge located at least partially in the package interposer.

FIG. 13 illustrates an exemplary flow chart of a method for fabricating a package that includes at least one integrated device, a package interposer comprising a passive device and a bridge located at least partially in the package interposer.

FIGS. 14A-14E illustrate an exemplary sequence for fabricating a package that includes at least one integrated device, a package interposer comprising a passive device and a bridge located at least partially in the package interposer.

FIG. 15 illustrates an exemplary flow chart of a method for fabricating a package that includes at least one integrated device, a package interposer comprising a passive device and a bridge located at least partially in the package interposer.

FIGS. 16A-16B illustrate an exemplary sequence for fabricating a metallization portion.

FIG. 17 illustrates an exemplary flow chart of a method for fabricating a metallization portion.

FIG. 18 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure a package comprising a first integrated device; a second integrated device; and a package interposer coupled to the first integrated device and the second integrated device. The package interposer comprises a first metallization portion; a second metallization portion; an encapsulation layer coupled to the first metallization portion and the second metallization portion; and a passive device located at least partially in the encapsulation layer. The encapsulation layer and the passive device are located between the first metallization portion and the second metallization portion. In some implementations, the passive device may include a deep trench capacitor device. In some implementations, the package interposer may include a bridge located at least partially in the encapsulation layer. In some implementations, a package may include a first integrated device; a second integrated device; and a package interposer coupled to the first integrated device and the second integrated device. The package interposer may comprise a first metallization portion; a second metallization portion; an encapsulation layer coupled to the first metallization portion and the second metallization portion; and a bridge located at least partially in the encapsulation layer. The encapsulation layer and the bridge are located between the first metallization portion and the second metallization portion. As will be further described below, the use of a passive device and/or a bridge that are at least partially embedded in the package interposer may help improve the performance of the package, while also minimizing the overall form factor of the package.

### Exemplary Package Comprising a Package Interposer, and a Passive Device and a Bridge, Located at Least Partially in the Package Interposer

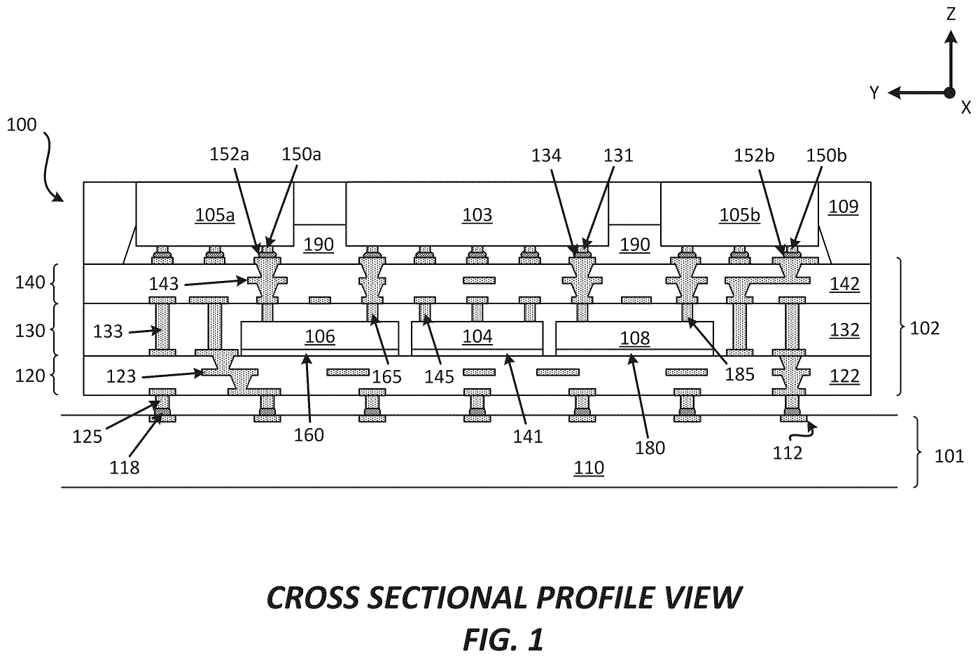

FIG. 1 illustrates a cross sectional profile view of a package 100 that includes a package interposer and a passive device embedded in the package interposer. The package 100 is coupled to a board 101 through a plurality of solder interconnects 118. The board 101 includes at least one board dielectric layer 110 and a plurality of board interconnects 112. The board 101 may include a printed circuit board (PCB). In some implementations, instead of the board 101, the package 100 may be coupled to a substrate (e.g., laminated substrate) through the plurality of solder interconnects 118.

The package 100 includes a package interposer 102, an integrated device 103, an integrated device 105a, an integrated device 105b, an underfill 190 and an encapsulation layer 109. The integrated device 105a and/or the integrated device 105b may include a memory (e.g., memory die, memory integrated device). In some implementations, the integrated device 103 may include a system on chip (SoC). In some implementations, the integrated device 105a may include a first memory integrated device (e.g., first high density memory die). In some implementations, the integrated device 105b may include a second memory integrated device (e.g., second high density memory die).

The package interposer 102 includes a metallization portion 120, an encapsulated portion 130, a metallization portion 140, and a plurality of pillar interconnects 125. In some implementations, the metallization portion 120 may be a first metallization portion and the metallization portion 140 may be a second metallization portion. The encapsulated portion 130 is coupled to the metallization portion 120 and the metallization portion 140. The encapsulated portion 130 is located between the metallization portion 120 and the metallization portion 140. The metallization portion 120 includes at least one dielectric layer 122 and a plurality of metallization interconnects 123. The at least one dielectric layer 122 may include prepreg and/or polyimide. The metallization portion 140 includes at least one dielectric layer 142 and a plurality of metallization interconnects 143. The at least one dielectric layer 142 may include prepreg and/or polyimide. The plurality of pillar interconnects 125 are coupled to the plurality of metallization interconnects 123 of the metallization portion 120. The plurality of pillar interconnects 125 are coupled to the plurality of solder interconnects 118.

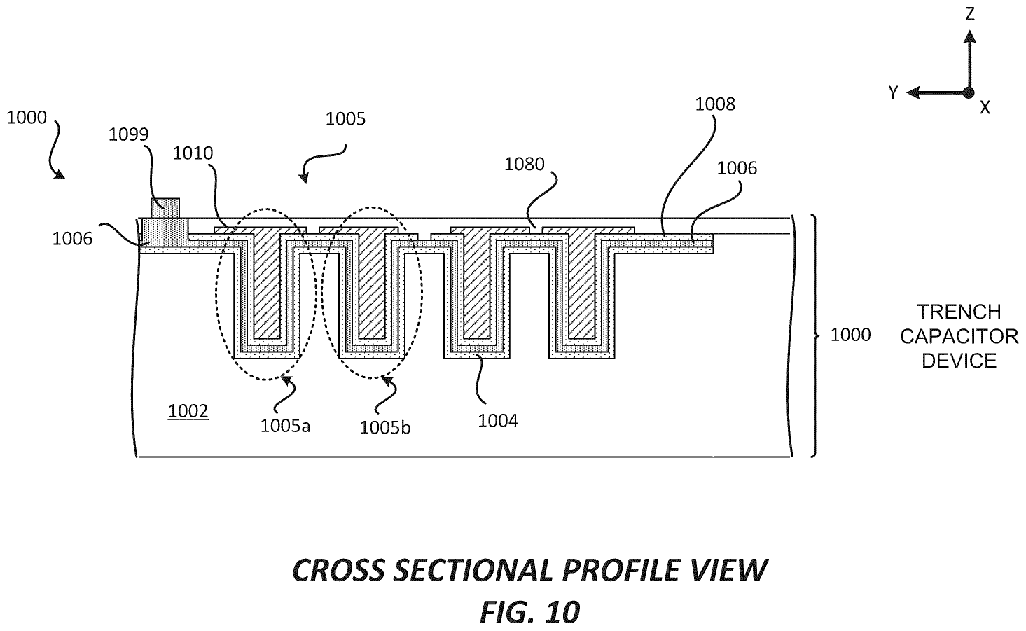

The encapsulated portion 130 includes an encapsulation layer 132 and a plurality of post interconnects 133. The encapsulated portion 130 also includes a passive device 104, a bridge 106 and a bridge 108. The passive device 104, the bridge 106 and/or the bridge 108 may be located at least partially in the encapsulation layer 132. Thus, the encapsulation layer 132 may at least partially encapsulate the passive device 104, the bridge 106, the bridge 108 and/or the plurality of post interconnects 133. The passive device 104 may include a deep trench capacitor device, such as the one illustrated and described in at least FIG. 10. The bridge 106 may include a silicon bridge. The bridge 106 may include a bridge substrate (e.g., silicon substrate, silicon bridge substrate) and a plurality of bridge interconnects. The bridge 106 may also include at least one bridge dielectric layer. The bridge 108 may include a silicon bridge. The bridge 108 may include a bridge substrate (e.g., silicon substrate, silicon bridge substrate) and a plurality of bridge interconnects. The bridge 108 may also include at least one bridge dielectric layer. The passive device 104 may include a plurality of post interconnects 145. The bridge 106 may include a plurality of post interconnects 162. The bridge 108 may include a plurality of post interconnects 182. The plurality of post interconnects 133, the plurality of post interconnects 145, the plurality of post interconnects 165 and/or the plurality of post interconnects 185 may be located at least partially in the encapsulation layer 132. The encapsulation layer 132 may include a mold, a resin and/or an epoxy. The encapsulation layer 132 may be a means for encapsulation. The encapsulation layer 132 may be provided by using a compression and transfer molding process, a sheet molding process, or a liquid molding process. A back side of the passive device 104 is coupled to the metallization portion 120 through an adhesive 141 (e.g., die attach film (DAF)). A back side of the bridge 106 is coupled to the metallization portion 120 through an adhesive 160 (e.g., DAF). A back side of the bridge 108 is coupled to the metallization portion 120 through an adhesive 180 (e.g., DAF).

The plurality of post interconnects 133 extend through the encapsulation layer 132. The plurality of post interconnects 133 are coupled to the metallization portion 120 and the metallization portion 140. For example, the plurality of post interconnects 133 may be coupled to (i) the plurality of metallization interconnects 123 of the metallization portion 120 and (ii) the plurality of metallization interconnects 143 of the metallization portion 140. The plurality of post interconnects 145 are coupled to the passive device 104 and the plurality of metallization interconnects 143 of the metallization portion 140. The plurality of post interconnects 165 are coupled to the bridge 106 and the plurality of metallization interconnects 143 of the metallization portion 140. The plurality of post interconnects 185 are coupled to the bridge 108 and the plurality of metallization interconnects 143 of the metallization portion 140.

The encapsulation layer 132, the passive device 104, the bridge 106, the bridge 108, the plurality of post interconnects 133, the plurality of post interconnects 145, the plurality of post interconnects 165 and the plurality of post interconnects 185 are located between the metallization portion 120 and the metallization portion 140. The encapsulation layer 132 is coupled to the metallization portion 120 and the metallization portion 140. In some implementations, some of the metallization interconnects from the plurality of metallization interconnects 123 may be at least partially encapsulated by the encapsulation layer 132.

The integrated device 103 is coupled to the metallization portion 140 through a plurality of pillar interconnects 131 and a plurality of solder interconnects 134. The plurality of pillar interconnects 131 and the plurality of solder interconnects 134 may represent a plurality of bump interconnects. The integrated device 105a is coupled to the metallization portion 140 through a plurality of pillar interconnects 150a and a plurality of solder interconnects 152a. The plurality of pillar interconnects 150a and the plurality of solder interconnects 152a may represent a plurality of bump interconnects. The integrated device 105b is coupled to the metallization portion 140 through a plurality of pillar interconnects 150b and a plurality of solder interconnects 152b. The plurality of pillar interconnects 150b and the plurality of solder interconnects 152b may represent a plurality of bump interconnects.

An underfill 190 is located between the integrated device 103 and the package interposer 102. The underfill 190 is located between the integrated device 105a and the package interposer 102. The underfill 190 is located between the integrated device 105b and the package interposer 102. The underfill 190 may be located between the integrated device 103 and the integrated device 105a. The underfill 190 may be located between the integrated device 103 and the integrated device 105b. In some implementations, the underfill 190 may include a composite material comprising an epoxy polymer with filler. An encapsulation layer 109 may be located over the package interposer 102. The package interposer 102 may be coupled to the metallization portion 140, the underfill 190, the integrated device 103, the integrated device 105a, and/or the integrated device 105b. The encapsulation layer 109 may include a mold, a resin and/or an epoxy. The encapsulation layer 109 may be a means for encapsulation. The encapsulation layer 109 may be provided by using a compression and transfer molding process, a sheet molding process, or a liquid molding process. The encapsulation layer 109 may be different from the underfill 190. For example, the encapsulation layer 109 may include a different material and/or a different composition of material from the underfill 190.

The passive device 104 is configured to be electrically coupled to the integrated device 103 through the metallization portion 140. An electrical path between the integrated device 103 and the passive device 104 may include (i) a pillar interconnect from the plurality of pillar interconnects 131, (ii) a solder interconnect from the plurality of solder interconnects 134, (iii) at least one metallization interconnect from the plurality of metallization interconnects 143, and/or (iv) a post interconnect from the plurality of post interconnects 145.

In some implementations, the integrated device 103 is configured to be electrically coupled to the integrated device 105a through the metallization portion 140. An electrical path between the integrated device 103 and the integrated device 105a may include (i) a pillar interconnect from the plurality of pillar interconnects 131, (ii) a solder interconnect from the plurality of solder interconnects 134, (iii) at least one metallization interconnect from the plurality of metallization interconnects 143, (iv) a solder interconnect from the plurality of solder interconnects 152a and/or (v) a pillar interconnect from the plurality of pillar interconnects 150a.

In some implementations, the integrated device 103 is configured to be electrically coupled to the integrated device 105a through the metallization portion 140 and the bridge 106. An electrical path between the integrated device 103 and the integrated device 105a may include (i) a pillar interconnect from the plurality of pillar interconnects 131, (ii) a solder interconnect from the plurality of solder interconnects 134, (iii) at least one metallization interconnect from the plurality of metallization interconnects 143, (iv) a post interconnect from the plurality of post interconnects 165, (v) the bridge 106 (e.g., bridge interconnects from the bridge 106), (vi) another post interconnect from the plurality of post interconnects 165, (vii) at least one other metallization interconnect from the plurality of metallization interconnects 143, (viii) a solder interconnect from the plurality of solder interconnects 152a and/or (ix) a pillar interconnect from the plurality of pillar interconnects 150a.

In some implementations, the integrated device 103 is configured to be electrically coupled to the integrated device 105b through the metallization portion 140. An electrical path between the integrated device 103 and the integrated device 105b may include (i) a pillar interconnect from the plurality of pillar interconnects 131, (ii) a solder interconnect from the plurality of solder interconnects 134, (iii) at least one metallization interconnect from the plurality of metallization interconnects 143, (iv) a solder interconnect from the plurality of solder interconnects 152b and/or (ix) a pillar interconnect from the plurality of pillar interconnects 150b.

In some implementations, the integrated device 103 is configured to be electrically coupled to the integrated device 105b through the metallization portion 140 and the bridge 108. An electrical path between the integrated device 103 and the integrated device 105a may include (i) a pillar interconnect from the plurality of pillar interconnects 131, (ii) a solder interconnect from the plurality of solder interconnects 134, (iii) at least one metallization interconnect from the plurality of metallization interconnects 143, (iv) a post interconnect from the plurality of post interconnects 185, (v) the bridge 108 (e.g., bridge interconnects from the bridge 108), (vi) another post interconnect from the plurality of post interconnects 185, (vii) at least one other metallization interconnect from the plurality of metallization interconnects 143, (viii) a solder interconnect from the plurality of solder interconnects 152b and/or (ix) a pillar interconnect from the plurality of pillar interconnects 150b.

Embedding the passive device 104 in the package interposer 102, helps provide a passive device that is closer the integrated device 103, which can help improve the performance of the package 100, such as improving the performance of the power distribution network of the package. This can lead to improved performance for the integrated device 103, the integrated device 105a and/or the integrated device 105b. Embedding the bridge 106 and/or the bridge 108 in the package interposer 102 helps provide more electrical paths for the package interposer 102 without necessarily increasing the size of the package interposer 102.

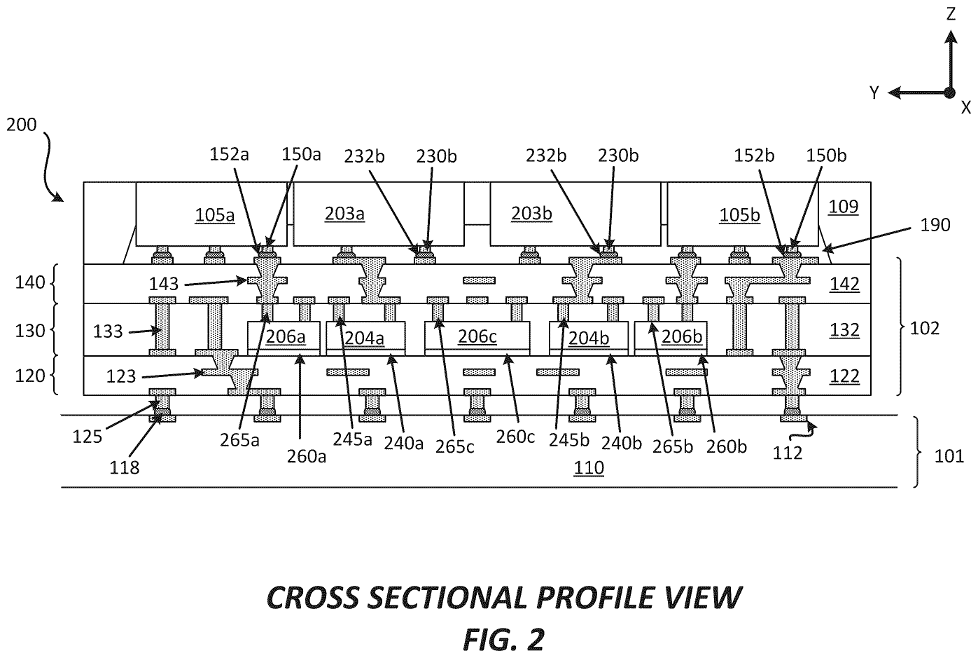

FIG. 2 illustrates a cross sectional profile view of a package 200 that includes a package interposer and a passive device and a bridge embedded in the package interposer. The package 200 is similar to the package 100. However, the package 200 includes more components than the package 100.

The package 200 includes a package interposer 102, an integrated device 203a, an integrated device 203b, an integrated device 105a, an integrated device 105b, an underfill 190 and an encapsulation layer 109. The integrated device 105a and/or the integrated device 105b may include a memory (e.g., memory die, memory integrated device). In some implementations, the integrated device 203a may include a first system on chip (SoC). In some implementations, the integrated device 203b may include a second system on chip (SoC). In some implementations, the integrated device 105a may include a first memory integrated device (e.g., first high density memory die). In some implementations, the integrated device 105b may include a second memory integrated device (e.g., second high density memory die).

The package interposer 102 includes a metallization portion 120, an encapsulated portion 130, a metallization portion 140, and a plurality of pillar interconnects 125. The encapsulated portion 130 is located between the metallization portion 120 and the metallization portion 140. The encapsulated portion 130 includes an encapsulation layer 132, a plurality of post interconnects 133, a passive device 204a, a passive device 204b, a bridge 206a, a bridge 206b, a bridge 206c, a plurality of post interconnects 245a, a plurality of post interconnects 245b, a plurality of post interconnects 265a, a plurality of post interconnects 265b, and a plurality of post interconnects 265c. The passive device 204a and/or the passive device 204b may include a deep trench capacitor, as illustrated and described in FIG. 10. The encapsulation layer 132, the plurality of post interconnects 133, the passive device 204a, the passive device 204b, the bridge 206a, the bridge 206b, the bridge 206c, the plurality of post interconnects 245a, the plurality of post interconnects 245b, the plurality of post interconnects 265a, the plurality of post interconnects 265b, and the plurality of post interconnects 265c are located between the metallization portion 120 and the metallization portion 140.

The passive device 204a is configured to be electrically coupled to the integrated device 203a through the metallization portion 140. An electrical path between the integrated device 203a and the passive device 204a may include (i) a pillar interconnect from the plurality of pillar interconnects 230a, (ii) a solder interconnect from the plurality of solder interconnects 232a, (iii) at least one metallization interconnect from the plurality of metallization interconnects 143, and/or (iv) a post interconnect from the plurality of post interconnects 245a.

The passive device 204b is configured to be electrically coupled to the integrated device 203b through the metallization portion 140. An electrical path between the integrated device 203b and the passive device 204b may include (i) a pillar interconnect from the plurality of pillar interconnects 230b, (ii) a solder interconnect from the plurality of solder interconnects 232b, (iii) at least one metallization interconnect from the plurality of metallization interconnects 143, and/or (iv) a post interconnect from the plurality of post interconnects 245b.

The integrated device 203a is configured to be electrically coupled to the integrated device 105a through the metallization portion 140 and the bridge 206a. An electrical path between the integrated device 203a and the integrated device 105a may include (i) a pillar interconnect from the plurality of pillar interconnects 230a, (ii) a solder interconnect from the plurality of solder interconnects 232a, (iii) at least one metallization interconnect from the plurality of metallization interconnects 143, (iv) a post interconnect from the plurality of post interconnects 265a, (v) the bridge 206a (e.g., bridge interconnects from the bridge 206a), (vi) another post interconnect from the plurality of post interconnects 265a, (vii) at least one other metallization interconnect from the plurality of metallization interconnects 143, (viii) a solder interconnect from the plurality of solder interconnects 152a and/or (ix) a pillar interconnect from the plurality of pillar interconnects 150a. In some implementations, an electrical path between the integrated device 203a and the integrated device 105a may bypass and/or skip the bridge 206a and/or the plurality of post interconnects 265a.

The integrated device 203b is configured to be electrically coupled to the integrated device 105b through the metallization portion 140 and the bridge 206b. An electrical path between the integrated device 203b and the integrated device 105b may include (i) a pillar interconnect from the plurality of pillar interconnects 230b, (ii) a solder interconnect from the plurality of solder interconnects 232b, (iii) at least one metallization interconnect from the plurality of metallization interconnects 143, (iv) a post interconnect from the plurality of post interconnects 265b, (v) the bridge 206b (e.g., bridge interconnects from the bridge 206b), (vi) another post interconnect from the plurality of post interconnects 265b, (vii) at least one other metallization interconnect from the plurality of metallization interconnects 143, (viii) a solder interconnect from the plurality of solder interconnects 152b and/or (ix) a pillar interconnect from the plurality of pillar interconnects 150b. In some implementations, an electrical path between the integrated device 203b and the integrated device 105b may bypass and/or skip the bridge 206b and/or the plurality of post interconnects 265b.

The integrated device 203a is configured to be electrically coupled to the integrated device 203b through the metallization portion 140 and the bridge 206c. An electrical path between the integrated device 203a and the integrated device 203b may include (i) a pillar interconnect from the plurality of pillar interconnects 230a, (ii) a solder interconnect from the plurality of solder interconnects 232a, (iii) at least one metallization interconnect from the plurality of metallization interconnects 143, (iv) a post interconnect from the plurality of post interconnects 265c, (v) the bridge 206c (e.g., bridge interconnects from the bridge 206c), (vi) another post interconnect from the plurality of post interconnects 265c, (vii) at least one other metallization interconnect from the plurality of metallization interconnects 143, (viii) a solder interconnect from the plurality of solder interconnects 232b and/or (ix) a pillar interconnect from the plurality of pillar interconnects 230b. In some implementations, an electrical path between the integrated device 203a and the integrated device 203b may bypass and/or skip the bridge 206c and/or the plurality of post interconnects 265c.

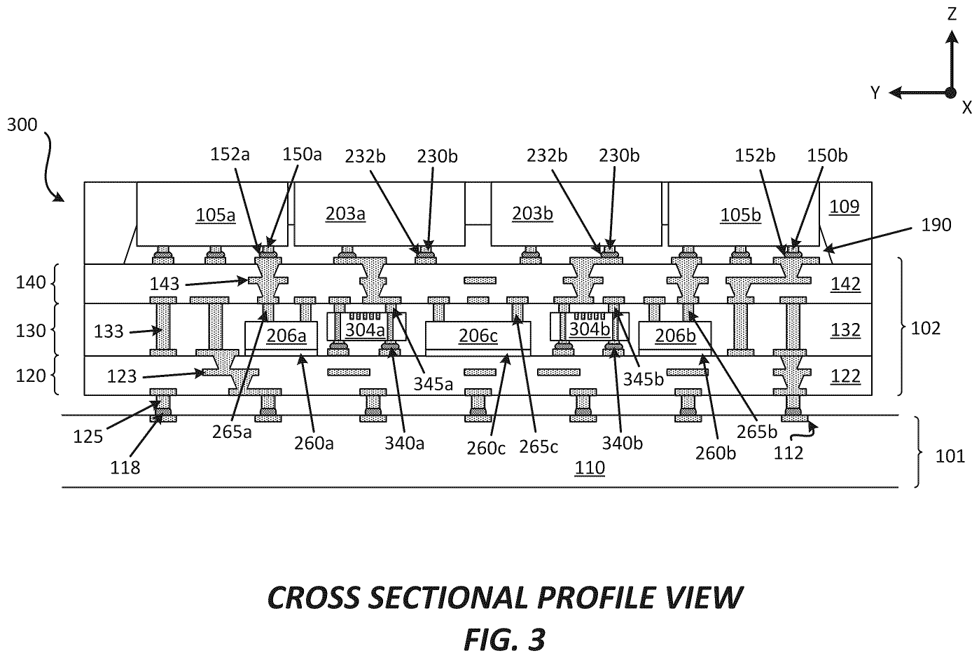

FIG. 3 illustrates a cross sectional profile view of a package 300 that includes a package interposer, and a passive device and a bridge embedded in the package interposer. The package 300 is similar to the package 200. However, the package 300 includes passive devices that are different from the passive devices of the package 200. The electrical paths described for the package 200 may be applicable to the package 300.

The package 300 includes a package interposer 102, an integrated device 203a, an integrated device 203b, an integrated device 105a, an integrated device 105b, an underfill 190 and an encapsulation layer 109.

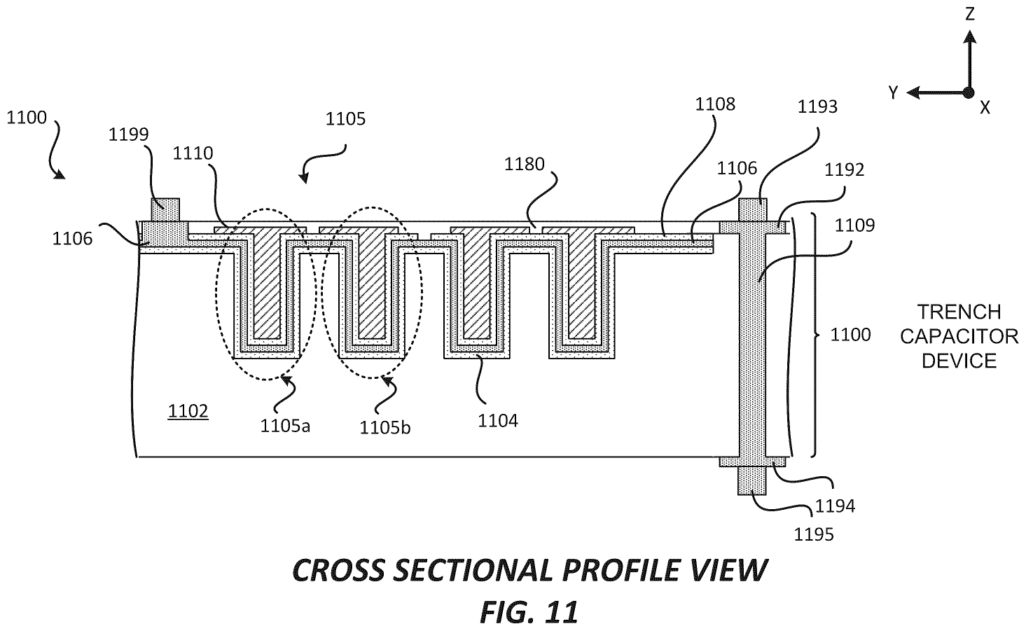

The package interposer 102 includes a metallization portion 120, an encapsulated portion 130, a metallization portion 140, and a plurality of pillar interconnects 125. The encapsulated portion 130 is located between the metallization portion 120 and the metallization portion 140. The encapsulated portion 130 includes an encapsulation layer 132, a plurality of post interconnects 133, a passive device 304a, a passive device 304b, a bridge 206a, a bridge 206b, a bridge 206c, a plurality of post interconnects 245a, a plurality of post interconnects 245b, a plurality of post interconnects 265a, a plurality of post interconnects 265b, and a plurality of post interconnects 265c. The passive device 304a and/or the passive device 304b may include a deep trench capacitor device, as illustrated and described in FIG. 11. The passive device 304a and/or the passive device 304b may be a deep trench capacitor device that includes at least one through substrate via.

The encapsulation layer 132, the plurality of post interconnects 133, the passive device 304a, the passive device 304b, the bridge 206a, the bridge 206b, the bridge 206c, the plurality of post interconnects 345a, the plurality of post interconnects 345b, the plurality of post interconnects 265a, the plurality of post interconnects 265b, and the plurality of post interconnects 265c are located between the metallization portion 120 and the metallization portion 140. The passive device 304a is coupled to the plurality of metallization interconnects 123 of the metallization portion 120 through a plurality of solder interconnects 340a. The passive device 304b is coupled to the plurality of metallization interconnects 123 of the metallization portion 120 through a plurality of solder interconnects 340b. The passive device 304a may include a front side and a back side. The front side of the passive device 304a may be a side that include one or more deep trench capacitors. The front side of the passive device 304a is closest to the metallization portion 140. The passive device 304b may include a front side and a back side. The front side of the passive device 304b may be a side that include one or more deep trench capacitors. The front side of the passive device 304b is closest to the metallization portion 140.

The passive device 304a may be configured to be provide an electrical path between the metallization portion 120 and the metallization portion 140. The passive device 304b may be configured to be provide an electrical path between the metallization portion 120 and the metallization portion 140.

The passive device 304a may be configured to be electrically coupled to the integrated device 203a through the metallization portion 140. An electrical path between the passive device 304a and the integrated device 203a may include (i) a post interconnect from the plurality of post interconnects 345a, (ii) at least one metallization interconnect from the plurality of metallization interconnects 143, (iii) a solder interconnect from the plurality of solder interconnects 232a, and/or (iv) a pillar interconnect from the plurality of pillar interconnects 230a.

An electrical path between the metallization portion 120 and the integrated device 203a may include the passive device 304a and the metallization portion 140. An electrical path between the metallization portion 120 and the integrated device 203a may include (i) a metallization interconnect from the plurality of metallization interconnects 123, (ii) a solder interconnect from the plurality of solder interconnects 340a, (iii) the passive device 304a (e.g., through substrate via of the passive device 304a), (iv) a post interconnect from the plurality of post interconnects 345a, (v) at least one metallization interconnect from the plurality of metallization interconnects 143, (vi) a solder interconnect from the plurality of solder interconnects 232a, and/or (vii) a pillar interconnect from the plurality of pillar interconnects 230a.

The passive device 304b may be configured to be electrically coupled to the integrated device 203b through the metallization portion 140. An electrical path between the passive device 304b and the integrated device 203b may include (i) a post interconnect from the plurality of post interconnects 345b, (ii) at least one metallization interconnect from the plurality of metallization interconnects 143, (iii) a solder interconnect from the plurality of solder interconnects 232b, and/or (iv) a pillar interconnect from the plurality of pillar interconnects 230b.

An electrical path between the metallization portion 120 and the integrated device 203b may include the passive device 304b and the metallization portion 140. An electrical path between the metallization portion 120 and the integrated device 203b may include (i) a metallization interconnect from the plurality of metallization interconnects 123, (ii) a solder interconnect from the plurality of solder interconnects 340b, (iii) the passive device 304b (e.g., through substrate via of the passive device 304b), (iv) a post interconnect from the plurality of post interconnects 345b, (v) at least one metallization interconnect from the plurality of metallization interconnects 143, (vi) a solder interconnect from the plurality of solder interconnects 232b, and/or (vii) a pillar interconnect from the plurality of pillar interconnects 230b.

In some implementations, an electrical path between the metallization portion 120 and the metallization portion 140 may include the passive device 304a and/or the passive device 304b. In some implementations, an electrical path between the metallization portion 120 and the metallization portion 140 may include the plurality of post interconnects 133.

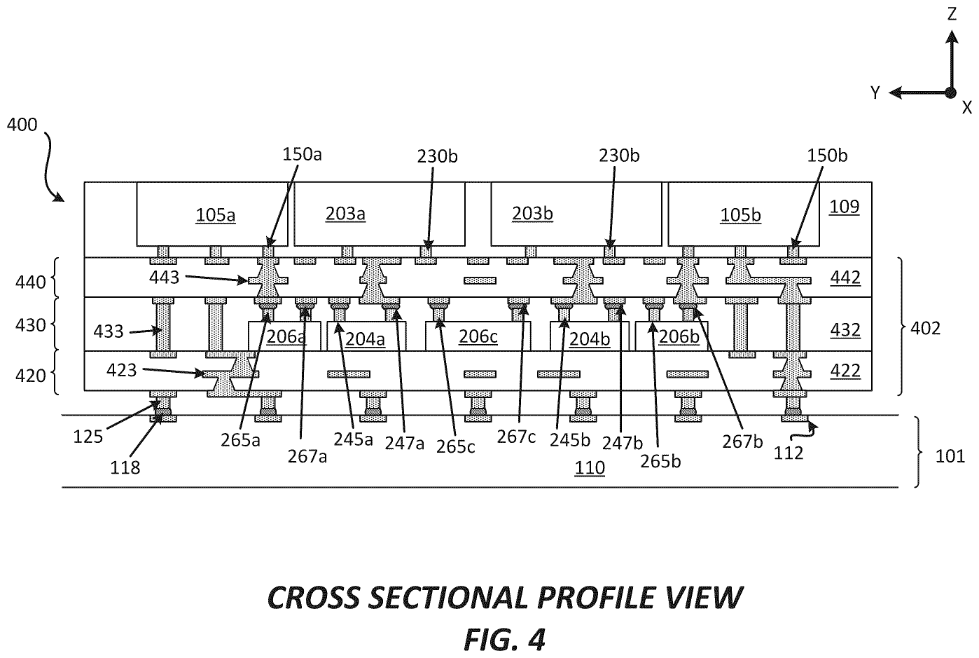

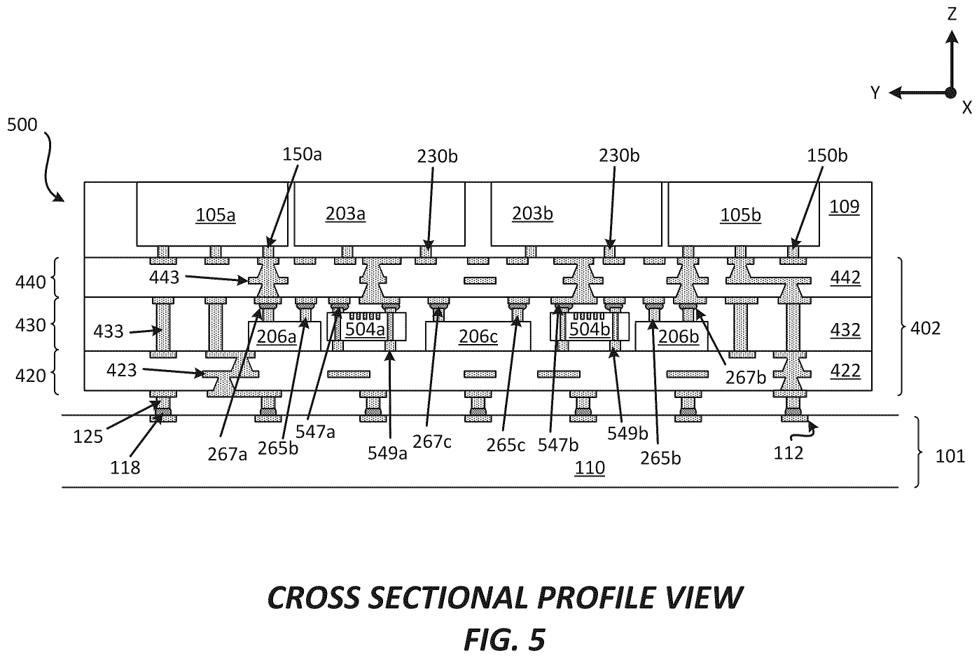

FIGS. 1-3 illustrate examples of packages that may be fabricated using a chip last approach. In some implementations, a package may be fabricated using a chip first approach. FIGS. 4-5 illustrate examples of packages that may be fabricated using a chip first approach.

FIG. 4 illustrates a cross sectional profile view of a package 400 that includes a package interposer and a passive device embedded in the package interposer. The package 400 is similar to the package 200. However, the package 400 includes a different configuration of components than the package 200.

The package 400 includes a package interposer 402, an integrated device 203a, an integrated device 203b, an integrated device 105a, an integrated device 105b and an encapsulation layer 109. The package 400 may be free of an underfill between the integrated device(s) (e.g., 203a, 203b, 105a, 105b) and the package interposer 402. The integrated device 105a and/or the integrated device 105b may include a memory (e.g., memory die, memory integrated device). In some implementations, the integrated device 203a may include a first system on chip (SoC). In some implementations, the integrated device 203b may include a second system on chip (SoC). In some implementations, the integrated device 105a may include a first memory integrated device (e.g., first high density memory die). In some implementations, the integrated device 105b may include a second memory integrated device (e.g., second high density memory die).

The package interposer 402 includes a metallization portion 420, an encapsulated portion 430, a metallization portion 440, and a plurality of pillar interconnects 125. The encapsulated portion 430 is located between the metallization portion 420 and the metallization portion 440. The encapsulated portion 430 includes an encapsulation layer 432, a plurality of post interconnects 433, a passive device 204a, a passive device 204b, a bridge 206a, a bridge 206b, a bridge 206c, a plurality of post interconnects 245a, a plurality of post interconnects 245b, a plurality of post interconnects 265a, a plurality of post interconnects 265b, and a plurality of post interconnects 265c. The encapsulation layer 432 may at least partially encapsulate the plurality of post interconnects 433, the passive device 204a, the passive device 204b, the bridge 206a, the bridge 206b, the bridge 206c, the plurality of post interconnects 245a, the plurality of post interconnects 245b, the plurality of post interconnects 265a, the plurality of post interconnects 265b, and the plurality of post interconnects 265c. The passive device 204a and/or the passive device 204b may include a deep trench capacitor device, as illustrated and described in FIG. 10. The encapsulation layer 432, the plurality of post interconnects 433, the passive device 204a, the passive device 204b, the bridge 206a, the bridge 206b, the bridge 206c, the plurality of post interconnects 245a, the plurality of post interconnects 245b, the plurality of post interconnects 265a, the plurality of post interconnects 265b, and the plurality of post interconnects 265c are located between the metallization portion 420 and the metallization portion 440.

The integrated device 203a is coupled to the metallization portion 440 of the package interposer 402 through the plurality of pillar interconnects 230a. The integrated device 203b is coupled to the metallization portion 440 of the package interposer 402 through the plurality of pillar interconnects 230b. The integrated device 105a is coupled to the metallization portion 440 of the package interposer 402 through the plurality of pillar interconnects 150a. The integrated device 105b is coupled to the metallization portion 440 of the package interposer 402 through the plurality of pillar interconnects 150b. The encapsulation layer 109 may be coupled to the metallization portion 440, the integrated device 203a, the integrated device 203b, the integrated device 105a and/or the integrated device 105b. The encapsulation layer 109 may at least partially encapsulate the integrated device 203a, the integrated device 203b, the integrated device 105a and/or the integrated device 105b.

The passive device 204a is coupled to the plurality of metallization interconnects 443 of the metallization portion 440 through a plurality of post interconnects 245a and a plurality of solder interconnects 247a. The passive device 204a is configured to be electrically coupled to the integrated device 203a through the metallization portion 440. An electrical path between the integrated device 203a and the passive device 204a may include (i) a pillar interconnect from the plurality of pillar interconnects 230a, (ii) at least one metallization interconnect from the plurality of metallization interconnects 443, (iii) a solder interconnect from the plurality of solder interconnects 247a and/or (iv) a post interconnect from the plurality of post interconnects 245a.

The passive device 204b is coupled to the plurality of metallization interconnects 443 of the metallization portion 440 through a plurality of post interconnects 245b and a plurality of solder interconnects 247b. The passive device 204b is configured to be electrically coupled to the integrated device 203b through the metallization portion 440. An electrical path between the integrated device 203b and the passive device 204b may include (i) a pillar interconnect from the plurality of pillar interconnects 230b, (ii) at least one metallization interconnect from the plurality of metallization interconnects 443, (iii) a solder interconnect from the plurality of solder interconnects 247b and/or (iv) a post interconnect from the plurality of post interconnects 245b.

The integrated device 203a is configured to be electrically coupled to the integrated device 105a through the metallization portion 440 and the bridge 206a. The bridge 206a is coupled to the plurality of metallization interconnects 443 of the metallization portion 440 through a plurality of post interconnects 265a and a plurality of solder interconnects 267a. An electrical path between the integrated device 203a and the integrated device 105a may include (i) a pillar interconnect from the plurality of pillar interconnects 230a, (ii) at least one metallization interconnect from the plurality of metallization interconnects 443, (iii) a solder interconnect from the plurality of solder interconnects 267a, (iv) a post interconnect from the plurality of post interconnects 265a, (v) the bridge 206a (e.g., bridge interconnects from the bridge 206a), (vi) another post interconnect from the plurality of post interconnects 265a, (vii) another solder interconnect from the plurality of solder interconnects 267a, (viii) at least one other metallization interconnect from the plurality of metallization interconnects 443, and/or (ix) a pillar interconnect from the plurality of pillar interconnects 150a. In some implementations, an electrical path between the integrated device 203a and the integrated device 105a may bypass and/or skip the bridge 206a and/or the plurality of post interconnects 265a.

The integrated device 203b is configured to be electrically coupled to the integrated device 105b through the metallization portion 440 and the bridge 206b. The bridge 206b is coupled to the plurality of metallization interconnects 443 of the metallization portion 440 through a plurality of post interconnects 265b and a plurality of solder interconnects 267b. An electrical path between the integrated device 203b and the integrated device 105b may include (i) a pillar interconnect from the plurality of pillar interconnects 230b, (ii) at least one metallization interconnect from the plurality of metallization interconnects 443, (iii) a solder interconnect from the plurality of solder interconnects 267b, (iv) a post interconnect from the plurality of post interconnects 265b, (v) the bridge 206b (e.g., bridge interconnects from the bridge 206b), (vi) another post interconnect from the plurality of post interconnects 265b, (vii) another solder interconnect from the plurality of solder interconnects 267b, (viii) at least one other metallization interconnect from the plurality of metallization interconnects 443, and/or (ix) a pillar interconnect from the plurality of pillar interconnects 150b. In some implementations, an electrical path between the integrated device 203b and the integrated device 105a may bypass and/or skip the bridge 206b and/or the plurality of post interconnects 265b.

The integrated device 203a is configured to be electrically coupled to the integrated device 203b through the metallization portion 440 and the bridge 206c. The bridge 206c is coupled to the plurality of metallization interconnects 443 of the metallization portion 440 through a plurality of post interconnects 265c and a plurality of solder interconnects 267c. An electrical path between the integrated device 203a and the integrated device 203b may include (i) a pillar interconnect from the plurality of pillar interconnects 230a, (ii) at least one metallization interconnect from the plurality of metallization interconnects 443, (iii) a solder interconnect from the plurality of solder interconnects 267c, (iv) a post interconnect from the plurality of post interconnects 265c, (iv) the bridge 206c (e.g., bridge interconnects from the bridge 206c), (v) another post interconnect from the plurality of post interconnects 265c, (vi) another solder interconnect from the plurality of solder interconnects 267c, (vii) at least one other metallization interconnect from the plurality of metallization interconnects 443 and/or (viii) another pillar interconnect from the plurality of pillar interconnects 230b. In some implementations, an electrical path between the integrated device 203a and the integrated device 203b may bypass and/or the bridge 206c and/or the plurality of post interconnects 265c.

The back sides of the passive device 204a, the passive device 204b, the bridge 206a, the bridge 206b and/or the bridge 206c are coupled to and touching the metallization portion 420. Thus, there may not be an adhesive that is used to couple the passive device 204a, the passive device 204b, the bridge 206a, the bridge 206b and/or the bridge 206c to the metallization portion 420.

FIG. 5 illustrates a cross sectional profile view of a package 500 that includes a package interposer, and a passive device and a bridge embedded in the package interposer. The package 500 is similar to the package 400. However, the package 500 includes passive devices that are different from the passive devices of the package 400.

The package 500 includes a package interposer 402, an integrated device 203a, an integrated device 203b, an integrated device 105a, an integrated device 105b, and an encapsulation layer 109. The package 400 may be free of an underfill between the integrated device(s) (e.g., 203a, 203b, 105a, 105b) and the package interposer 402.

The package interposer 402 includes a metallization portion 420, an encapsulated portion 430, a metallization portion 440, and a plurality of pillar interconnects 125. The encapsulated portion 430 is located between the metallization portion 420 and the metallization portion 440. The encapsulated portion 430 includes an encapsulation layer 432, a plurality of post interconnects 433, a passive device 504a, a passive device 504b, a bridge 206a, a bridge 206b, a bridge 206c, a plurality of post interconnects 245a, a plurality of post interconnects 245b, a plurality of post interconnects 265a, a plurality of post interconnects 265b, a plurality of post interconnects 265c, a plurality of solder interconnects 267a, a plurality of solder interconnects 267b, a plurality of solder interconnects 547a, a plurality of solder interconnects 547b, a plurality of post interconnects 549a, and a plurality of post interconnects 549b. The encapsulation layer 432 may at least partially encapsulate the plurality of post interconnects 433, the passive device 504a, the passive device 504b, the bridge 206a, a bridge 206b, the bridge 206c, the plurality of post interconnects 245a, the plurality of post interconnects 245b, the plurality of post interconnects 265a, the plurality of post interconnects 265b, the plurality of post interconnects 265c, the plurality of solder interconnects 267a, the plurality of solder interconnects 267b, the plurality of solder interconnects 547a, the plurality of solder interconnects 547b, the plurality of post interconnects 549a, and/or the plurality of post interconnects 549b. The passive device 504a and/or the passive device 504b may include a deep trench capacitor device, as illustrated and described in FIG. 11. The passive device 504a and/or the passive device 504b may be a deep trench capacitor device that includes at least one through substrate via.

The encapsulation layer 432, the plurality of post interconnects 133, the passive device 304a, the passive device 304b, the bridge 206a, the bridge 206b, the bridge 206c, the plurality of post interconnects 345a, the plurality of post interconnects 345b, the plurality of post interconnects 265a, the plurality of post interconnects 265b, the plurality of post interconnects 265c, the plurality of solder interconnects 547a, the plurality of solder interconnects 547b, the plurality of post interconnects 549a, and/or the plurality of post interconnects 549b are located between the metallization portion 420 and the metallization portion 440.

The passive device 504a is coupled to the plurality of metallization interconnects 423 of the metallization portion 420 through a plurality of post interconnects 549a. The passive device 504a is coupled to the plurality of metallization interconnects 443 of the metallization portion 440 through a plurality of solder interconnects 547a.

The passive device 504b is coupled to the plurality of metallization interconnects 423 of the metallization portion 420 through a plurality of post interconnects 549b. The passive device 504b is coupled to the plurality of metallization interconnects 443 of the metallization portion 440 through a plurality of solder interconnects 547b.

The passive device 504a may include a front side and a back side. The front side of the passive device 504a may be a side that include one or more deep trench capacitors. The front side of the passive device 504a is closest to the metallization portion 440. The passive device 504b may include a front side and a back side. The front side of the passive device 504b may be a side that include one or more deep trench capacitors. The front side of the passive device 504b is closest to the metallization portion 440.

The passive device 504a may be configured to be provide an electrical path between the metallization portion 420 and the metallization portion 440. The passive device 504b may be configured to be provide an electrical path between the metallization portion 420 and the metallization portion 440.

The passive device 504a is configured to be electrically coupled to the integrated device 203a through the metallization portion 440. An electrical path between the metallization portion 420 and the integrated device 203a may include the passive device 504a and the metallization portion 440. An electrical path between the metallization portion 420 and the integrated device 203a may include (i) a metallization interconnect from the plurality of metallization interconnects 423, (ii) a post interconnect from the plurality of post interconnects 549a, (iii) the passive device 504a (e.g., through substrate via of the passive device 504a), (iv) a solder interconnect from the plurality of solder interconnects 547a, (v) at least one metallization interconnect from the plurality of metallization interconnects 443 and/or (vi) a pillar interconnect from the plurality of pillar interconnects 230a.

The passive device 504b is configured to be electrically coupled to the integrated device 203b through the metallization portion 440. An electrical path between the metallization portion 420 and the integrated device 203b may include the passive device 504b and the metallization portion 440. An electrical path between the metallization portion 420 and the integrated device 203b may include (i) a metallization interconnect from the plurality of metallization interconnects 423, (ii) a post interconnect from the plurality of post interconnects 549b, (iii) the passive device 504b (e.g., through substrate via of the passive device 504b), (iv) a solder interconnect from the plurality of solder interconnects 547b, (v) at least one metallization interconnect from the plurality of metallization interconnects 443 and/or (vi) a pillar interconnect from the plurality of pillar interconnects 230b.

In some implementations, an electrical path between the metallization portion 420 and the metallization portion 440 may include the passive device 504a and/or the passive device 504b. In some implementations, an electrical path between the metallization portion 420 and the metallization portion 440 may include the plurality of post interconnects 433.

Embedding one or more passive devices in the package interposer (e.g., 402, 402), helps provide a passive device that is closer the integrated devices, which can help improve the performance of the package, such as improving the performance of the power distribution network of the package. This can lead to improved performance for the integrated devices. Embedding one or more bridges in the package interposer helps provide more electrical paths for the package interposer without necessarily increasing the size of the package interposer.

FIGS. 1-5 illustrate packages that include a package interposer with two metallization portions. However, in some implementations, a package interposer may include one metallization portion. Thus, for example, in some implementations, the metallization portion 120 and/or the metallization portion 420 may be optional. In such instances, the plurality of pillar interconnects 125 may be coupled to the plurality of post interconnects 133 and/or the plurality of post interconnects 433. In some implementations, a metallization portion (e.g., 120, 140, 420, 440) may include one or more metal layers (e.g., M1 layer, M2 layer, M3 layer). Different implementations may have different metal layers for different metallization portions. A package interposer may be considered as a package substrate.

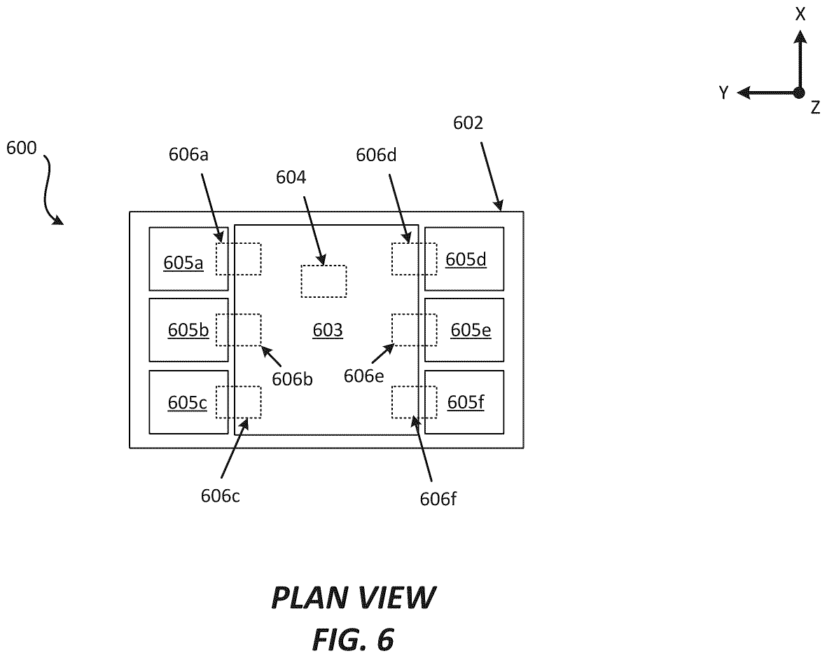

Different implementations may have different configurations and/or arrangements of the integrated devices, the bridges and/or the passive devices. FIGS. 6-9 illustrate examples of different configurations and/or arrangements of integrated devices, the bridges and/or the passive devices. FIGS. 6-9 may represent any of the packages described in the disclosure, including the packages of FIGS. 1-5.

FIG. 6 illustrates an exemplary plan view of a package 600 that includes a package interposer 602, an integrated device 603, a passive device 604, an integrated device 605a, an integrated device 605b, an integrated device 605c, an integrated device 605d, an integrated device 605e, an integrated device 605f, a bridge 606a, a bridge 606b, a bridge 606c, a bridge 606d, a bridge 606e, and a bridge 606f. The integrated devices 605a-605f may be configured as memory devices (e.g., high density memory dies). The integrated device 603 may be configured as a system on chip (SoC). The passive device 604 may include a deep trench capacitor device. The passive device 604 and the bridges 606a-606f are embedded in the package interposer 602. The integrated device 603 and the integrated devices 605a-605f are coupled to the package interposer 602.

The bridge 606a is configured to be provide an electrical path between the integrated device 603 and the integrated device 605a. The bridge 606b is configured to be provide an electrical path between the integrated device 603 and the integrated device 605b. The bridge 606c is configured to be provide an electrical path between the integrated device 603 and the integrated device 605c. The bridge 606d is configured to be provide an electrical path between the integrated device 603 and the integrated device 605d. The bridge 606e is configured to be provide an electrical path between the integrated device 603 and the integrated device 605e. The bridge 606f is configured to be provide an electrical path between the integrated device 603 and the integrated device 605f. The passive device 604 is configured to be electrically coupled to the integrated device 603. The passive device 604 may vertically overlap with the integrated device 603.

FIG. 6 illustrates that the integrated devices 605a-605c are located adjacent to a first side (e.g., left side) of the integrated device 603. The integrated devices 605d-605f are located adjacent to a second side (e.g., right side) of the integrated device 603.

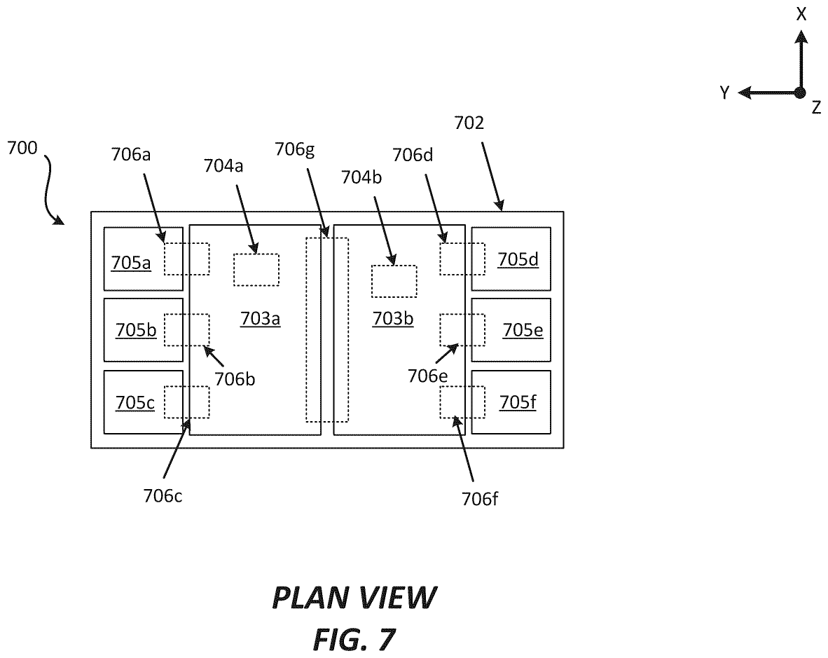

FIG. 7 illustrates an exemplary plan view of a package 700 that includes a package interposer 702, an integrated device 703a, an integrated device 703b, a passive device 704a, a passive device 704b, an integrated device 705a, an integrated device 705b, an integrated device 705c, an integrated device 705d, an integrated device 705e, an integrated device 705f, a bridge 706a, a bridge 706b, a bridge 706c, a bridge 706d, a bridge 706e, a bridge 706f, and a bridge 706g. The integrated devices 705a-705f may be configured as memory devices (e.g., high density memory). The integrated device 703a may be configured as a first system on chip (SoC). The integrated device 703b may be configured as a second system on chip (SoC). The passive device 704a may include a deep trench capacitor device. The passive device 704b may include a deep trench capacitor device. The passive device 704a, the passive device 704b and the bridges 706a-706f are embedded in the package interposer 702. The integrated device 703a, the integrated device 703b and the integrated devices 705a-705f are coupled to the package interposer 702.

The bridge 706a is configured to be provide an electrical path between the integrated device 703a and the integrated device 705a. The bridge 706b is configured to be provide an electrical path between the integrated device 703a and the integrated device 705b. The bridge 706c is configured to be provide an electrical path between the integrated device 703a and the integrated device 705c. The bridge 706d is configured to be provide an electrical path between the integrated device 703b and the integrated device 705d. The bridge 706e is configured to be provide an electrical path between the integrated device 703b and the integrated device 705e. The bridge 706f is configured to be provide an electrical path between the integrated device 703b and the integrated device 705f. The bridge 706g is configured to be provide an electrical path between the integrated device 703a and the integrated device 703b. The passive device 704a is configured to be electrically coupled to the integrated device 703a. The passive device 704b may vertically overlap with the integrated device 703b. The passive device 704b is configured to be electrically coupled to the integrated device 703b. The passive device 704b may vertically overlap with the integrated device 703b.

FIG. 7 illustrates that the integrated devices 705a-705c are located adjacent to a first side (e.g., left side) of the integrated device 703a. A second side (e.g., right side) of the integrated device 703a is adjacent to a first side (e.g., left side) of the integrated device 703b. The integrated devices 705d-705f are located adjacent to a second side (e.g., right side) of the integrated device 703b.

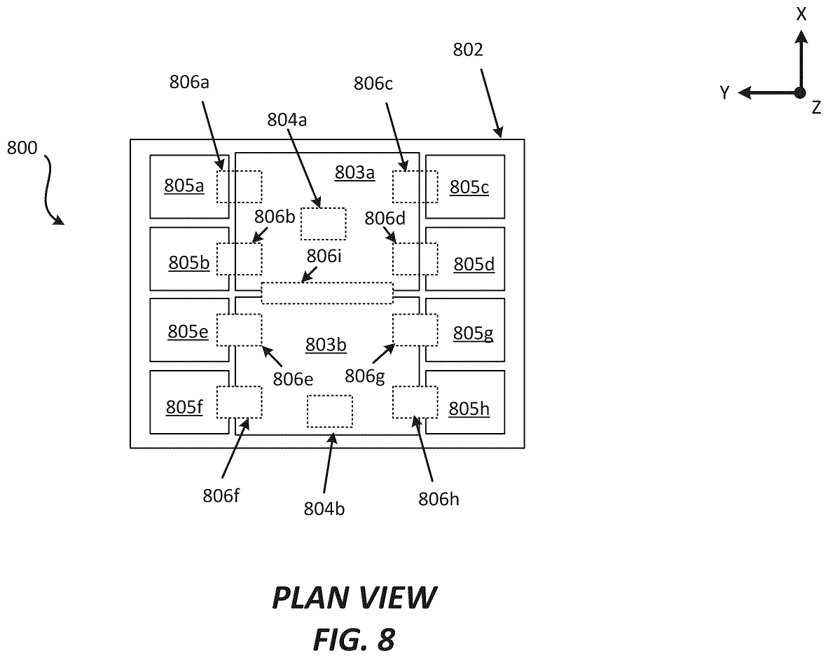

FIG. 8 illustrates an exemplary plan view of a package 800 that includes a package interposer 802, an integrated device 803a, an integrated device 803b, a passive device 804a, a passive device 804b, an integrated device 805a, an integrated device 805b, an integrated device 805c, an integrated device 805d, an integrated device 805e, an integrated device 805f, an integrated device 805g, an integrated device 805h, a bridge 806a, a bridge 806b, a bridge 806c, a bridge 806d, a bridge 806e, a bridge 806f, a bridge 806g, a bridge 806h, and a bridge 806i. The integrated devices 805a-805h may be configured as memory devices (e.g., high density memory). The integrated device 803a may be configured as a first system on chip (SoC). The integrated device 803b may be configured as a second system on chip (SoC). The passive device 804a may include a deep trench capacitor device. The passive device 804b may include a deep trench capacitor device. The passive device 804a, the passive device 804b and the bridges 806a-806h are embedded in the package interposer 802. The integrated device 803a, the integrated device 803b and the integrated devices 805a-805h are coupled to the package interposer 802.

The bridge 806a is configured to be provide an electrical path between the integrated device 803a and the integrated device 805a. The bridge 806b is configured to be provide an electrical path between the integrated device 803a and the integrated device 805b. The bridge 806c is configured to be provide an electrical path between the integrated device 803a and the integrated device 805c. The bridge 806d is configured to be provide an electrical path between the integrated device 803a and the integrated device 805d. The bridge 806e is configured to be provide an electrical path between the integrated device 803b and the integrated device 805e. The bridge 806f is configured to be provide an electrical path between the integrated device 803b and the integrated device 805f. The bridge 806g is configured to be provide an electrical path between the integrated device 803b and the integrated device 805g. The bridge 806h is configured to be provide an electrical path between the integrated device 803b and the integrated device 805h. The bridge 806i is configured to be provide an electrical path between the integrated device 803a and the integrated device 803b. The passive device 804a is configured to be electrically coupled to the integrated device 803a. The passive device 804b may vertically overlap with the integrated device 803b. The passive device 804b is configured to be electrically coupled to the integrated device 803b. The passive device 804b may vertically overlap with the integrated device 803b.

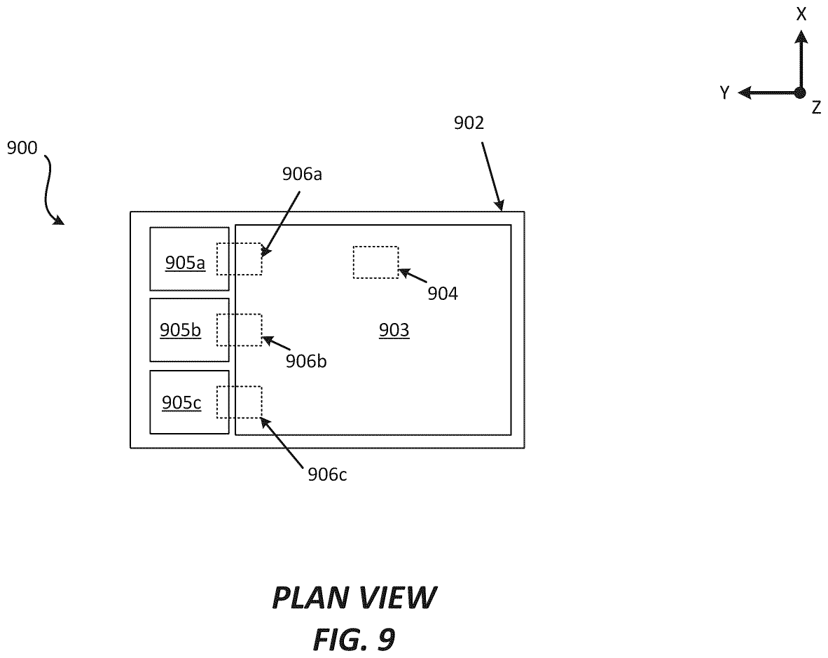

FIG. 9 illustrates an exemplary plan view of a package 900 that includes a package interposer 902, an integrated device 903, a passive device 904, an integrated device 905a, an integrated device 905b, an integrated device 905c, a bridge 906a, a bridge 906b, and a bridge 906c. The integrated devices 905a-905c may be configured as memory devices (e.g., high density memory). The integrated device 903 may be configured as a system on chip (SoC). The passive device 904 may include a deep trench capacitor device. The passive device 904 and the bridges 909a-909c are embedded in the package interposer 902. The integrated device 903 and the integrated devices 905a-905c are coupled to the package interposer 902.

The bridge 909a is configured to be provide an electrical path between the integrated device 903 and the integrated device 905a. The bridge 909b is configured to be provide an electrical path between the integrated device 903 and the integrated device 905b. The bridge 909c is configured to be provide an electrical path between the integrated device 903 and the integrated device 905c. The passive device 904 is configured to be electrically coupled to the integrated device 903. The passive device 904 may vertically overlap with the integrated device 903. The integrated device 905a-905c are located on one side of the integrated device 903. FIG. 9 illustrates that the integrated devices 905a-905c are located adjacent to a first side (e.g., left side) of the integrated device 903.

An integrated device (e.g., 103, 203, 105) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc.,). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing).

In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100) may be implemented in a radio frequency (RF) package. The RF package may be a radio frequency front end (RFFE) package. A package (e.g., 100) may be configured to provide Wireless Fidelity (WiFi) communication and/or cellular communication (e.g., 2G, 3G, 4G, 5G). The packages (e.g., 100) may be configured to support Global System for Mobile (GSM) Communications, Universal Mobile Telecommunications System (UMTS), and/or Long-Term Evolution (LTE). The packages (e.g., 100) may be configured to transmit and receive signals having different frequencies and/or communication protocols.

Exemplary Device/Chiplet with Deep Trench Capacitors

FIG. 10 illustrates a cross sectional profile view of a chiplet 1000 that is configured as a trench capacitor device. The chiplet 1000 may be a passive device. The chiplet 1000 may represent any of the passive devices described in the disclosure. For example, the chiplet 1000 may represent the passive device 204a. The chiplet 1000 may be an integrated passive device (e.g., passive device) that includes multiple trench capacitors (e.g., deep trench capacitors). The chiplet 1000 may be a means for trench capacitance. The chiplet 1000 includes a front side and a back side. The front side of the chiplet 1000 may include a side that includes the plurality of trench capacitors.

The chiplet 1000 includes a chiplet substrate 1002 (e.g., passive device substrate) and a plurality of trench capacitors 1005. A plurality of solder interconnects (not shown) may be coupled to the chiplet 1000. The chiplet substrate 1002 may include silicon (Si). The chiplet substrate 1002 may include a plurality of trenches and/or cavities over which capacitors may be formed.

The plurality of trench capacitors 1005 includes a trench capacitor 1005a and a trench capacitor 1005b. The trench capacitor 1005a and the trench capacitor 1005b may be configured to be part of a same capacitor (e.g., first capacitor, first trench capacitor). The trench capacitor 1005a and the trench capacitor 1005b may be configured to be coupled to and/or part of a first power distribution network (PDN). The trench capacitor 1005a and the trench capacitor 1005b may be configured to be part of a first electrical path for a first power for a package. The trench capacitor 1005a and the trench capacitor 1005b may be configured to be coupled to integrated device(s).

As shown in FIG. 10, the chiplet 1000 includes the chiplet substrate 1002, an oxide layer 1004, a first electrically conductive layer 1006, a dielectric layer 1008, a second electrically conductive layer 1010 and a dielectric layer 1080. The first electrically conductive layer 1006 and/or the second electrically conductive layer 1010 may include polysilicon. The oxide layer 1004 and/or the dielectric layer 1008 may include SiO₂ (e.g., low-pressure chemical vapor deposition (LPCVD) SiO₂) or Si₃N₄ (e.g., LPCVD Si₃N₄). Portions of the oxide layer 1004, the first electrically conductive layer 1006, the dielectric layer 1008, and the second electrically conductive layer 1010 may be located in trenches and/or cavities of the chiplet substrate 1002. The dielectric layer 1080 may include silicon nitride. It is noted that a chiplet substrate 1002 may be considered to have a trench or a cavity, even if the trench or the cavity is filled with one or more materials.

The trench capacitor 1005a (e.g., first trench capacitor, first capacitor, means for first trench capacitance) may be defined by (i) a first portion of the oxide layer 1004, (ii) a first portion of the first electrically conductive layer 1006, (iii) a first portion of the dielectric layer 1008, and (iv) a first portion of the second electrically conductive layer 1010 that are located in a trench (e.g., first trench) of the chiplet substrate 1002.

The trench capacitor 1005b (e.g., second trench capacitor, second capacitor, means for second trench capacitance) may be defined by (i) a second portion of the oxide layer 1004, (ii) a second portion of the first electrically conductive layer 1006, (iii) a second portion of the dielectric layer 1008, and (iv) a second portion of the second electrically conductive layer 1010 that are located in a trench (e.g., second trench) of the chiplet substrate 1002. It is noted that trench capacitor 1005b may be part of a same capacitor as the trench capacitor 1005a. That is, the trench capacitor 1005a and the trench capacitor 1005b may be configured to be electrically coupled together to form a capacitor (e.g., first capacitor) with a greater capacitance. The chiplet 1000 may also optionally include a post interconnect 1099 that is coupled to the first electrically conductive layer 1006. The chiplet may also include other post interconnects that are coupled to other second electrically conductive layer 1010.

In some implementations, a chiplet may also include a through substrate vias. FIG. 11 illustrates an example of a chiplet 1100 that includes a through substrate via. The chiplet 1100 is similar to the chiplet 1000. However, the chiplet 1100 includes at least one through substrate vias.

FIG. 11 illustrates a cross sectional profile view of a chiplet 1100 that is configured as a trench capacitor device. The chiplet 1100 may be a passive device. The chiplet 1100 may represent any of the passive device described in the disclosure. For example, the chiplet 1100 may represent the passive device(s) 304a, 304b, 504a and/or 504b. The chiplet 1100 may be an integrated passive device (e.g., passive device) that includes multiple trench capacitors (e.g., deep trench capacitors). The chiplet 1100 may be a means for trench capacitance. The chiplet 1100 includes a front side and a back side. The front side of the chiplet 1100 may include the plurality of trench capacitors.

The chiplet 1100 includes a chiplet substrate 1102 (e.g., passive device substrate) and a plurality of trench capacitors 1105. A plurality of solder interconnects (not shown) may be coupled to the chiplet 1100. The chiplet substrate 1102 may include silicon (Si). The chiplet substrate 1102 may include a plurality of trenches and/or cavities over which capacitors may be formed.

The plurality of trench capacitors 1105 includes a trench capacitor 1105a and a trench capacitor 1105b. The trench capacitor 1105a and the trench capacitor 1105b may be configured to be part of a same capacitor (e.g., first capacitor, first trench capacitor). The trench capacitor 1105a and the trench capacitor 1105b may be configured to be coupled to and/or part of a first power distribution network (PDN). The trench capacitor 1105a and the trench capacitor 1105b may be configured to be part of a first electrical path for a first power for a package. The trench capacitor 1105a and the trench capacitor 1105b may be configured to be coupled to integrated device(s).

As shown in FIG. 11, the chiplet 1100 includes the chiplet substrate 1102, an oxide layer 1104, a first electrically conductive layer 1106, a dielectric layer 1108, a second electrically conductive layer 1110 and a dielectric layer 1180. The first electrically conductive layer 1106 and/or the second electrically conductive layer 1110 may include polysilicon. The oxide layer 1104 and/or the dielectric layer 1108 may include SiO₂ (e.g., low-pressure chemical vapor deposition (LPCVD) SiO₂) or Si₃N₄ (e.g., LPCVD Si₃N₄). Portions of the oxide layer 1104, the first electrically conductive layer 1106, the dielectric layer 1108, and the second electrically conductive layer 1110 may be located in trenches and/or cavities of the chiplet substrate 1102. The dielectric layer 1180 may include silicon nitride. It is noted that a chiplet substrate 1102 may be considered to have a trench or a cavity, even if the trench or the cavity is filled with one or more materials.

The trench capacitor 1105a (e.g., first trench capacitor, first capacitor, means for first trench capacitance) may be defined by (i) a first portion of the oxide layer 1104, (ii) a first portion of the first electrically conductive layer 1106, (iii) a first portion of the dielectric layer 1108, and (iv) a first portion of the second electrically conductive layer 1110 that are located in a trench (e.g., first trench) of the chiplet substrate 1102.

The trench capacitor 1105b (e.g., second trench capacitor, second capacitor, means for second trench capacitance) may be defined by (i) a second portion of the oxide layer 1104, (ii) a second portion of the first electrically conductive layer 1106, (iii) a second portion of the dielectric layer 1108, and (iv) a second portion of the second electrically conductive layer 1110 that are located in a trench (e.g., second trench) of the chiplet substrate 1102. It is noted that trench capacitor 1105b may be part of a same capacitor as the trench capacitor 1105a. That is, the trench capacitor 1105a and the trench capacitor 1105b may be configured to be electrically coupled together to form a capacitor (e.g., first capacitor) with a greater capacitance. The chiplet 1100 may also optionally include a post interconnect 1199 that is coupled to the first electrically conductive layer 1106. The chiplet may also include other post interconnects that are coupled to other second electrically conductive layer 1110.

The chiplet 1100 also includes an interconnect 1109, an interconnect 1192, and an interconnect 1194. The interconnect 1109 is coupled to the interconnect 1192 and the interconnect 1194. The interconnect 1109 may be a through substrate via that extends through the chiplet substrate 1102. The interconnect 1192 may be a pad interconnect. The interconnect 1194 may be a pad interconnect. The interconnect 1192 may be located on the front side of the chiplet 1100. The interconnect 1192 may be located on the back side of the chiplet 1100. The interconnect 1109 may be a through chiplet substrate interconnect. The chiplet may include at least one through chiplet substrate interconnect. The interconnect 1192 may be part of a plurality of metallization interconnects (e.g., plurality of front side metallization interconnects). The interconnect 1194 may be part of a plurality of metallization interconnects (e.g., plurality of back side metallization interconnects). The chiplet 1100 may also optionally include a post interconnect 1193 and a post interconnect 1195. The post interconnect 1193 may be coupled to the interconnect 1192. The post interconnect 1195 may be coupled to the interconnect 1194.

### Exemplary Sequence for Fabricating a Package Comprising a Package Interposer and a Passive Device and a Bridge Located at Least Partially in the Package Interposer

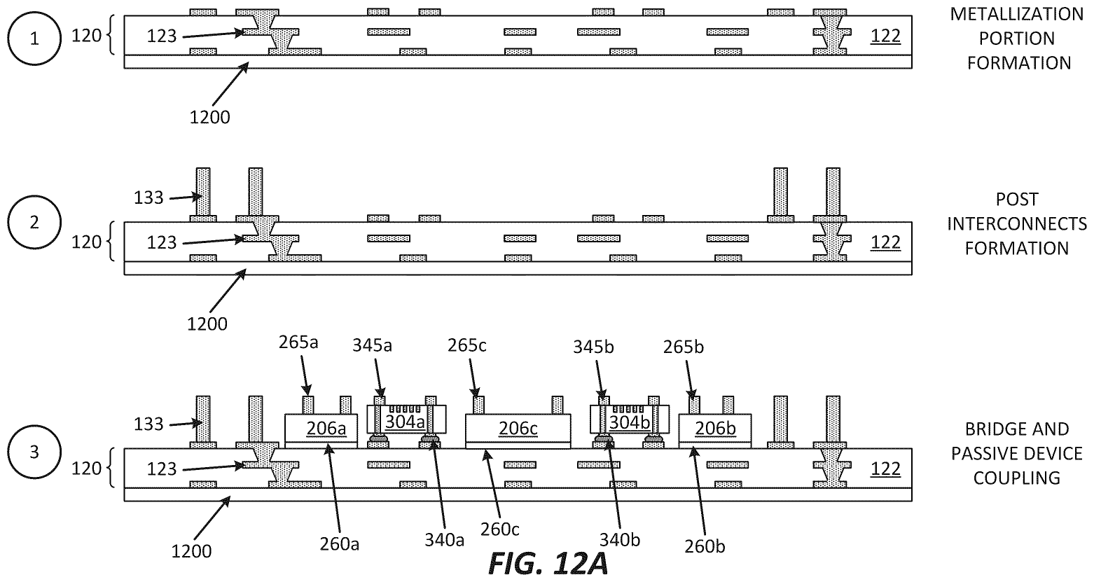

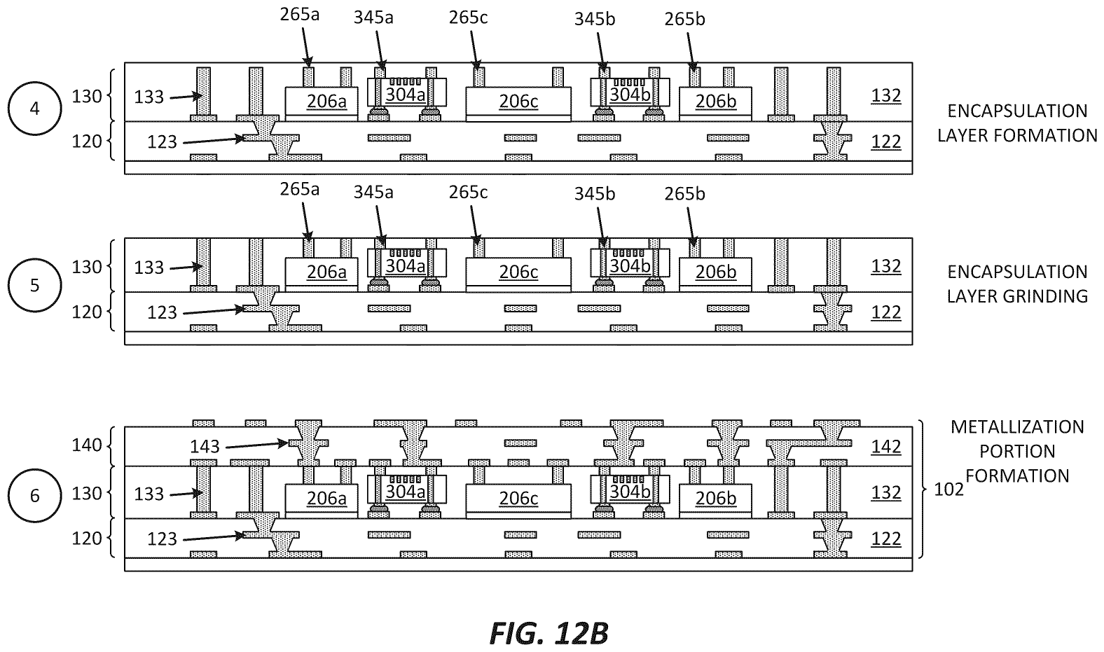

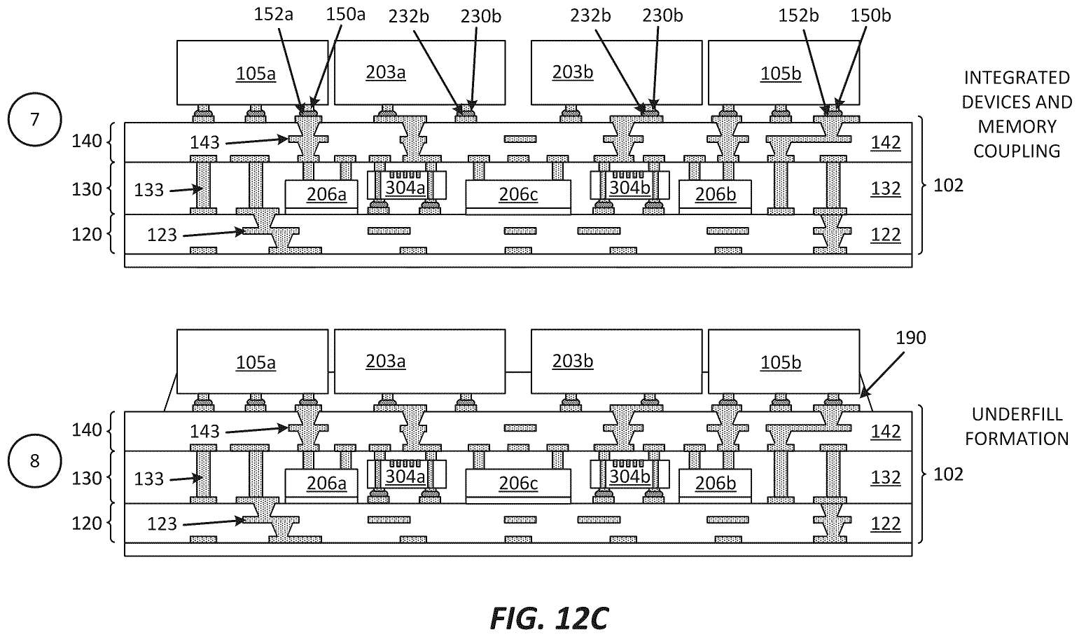

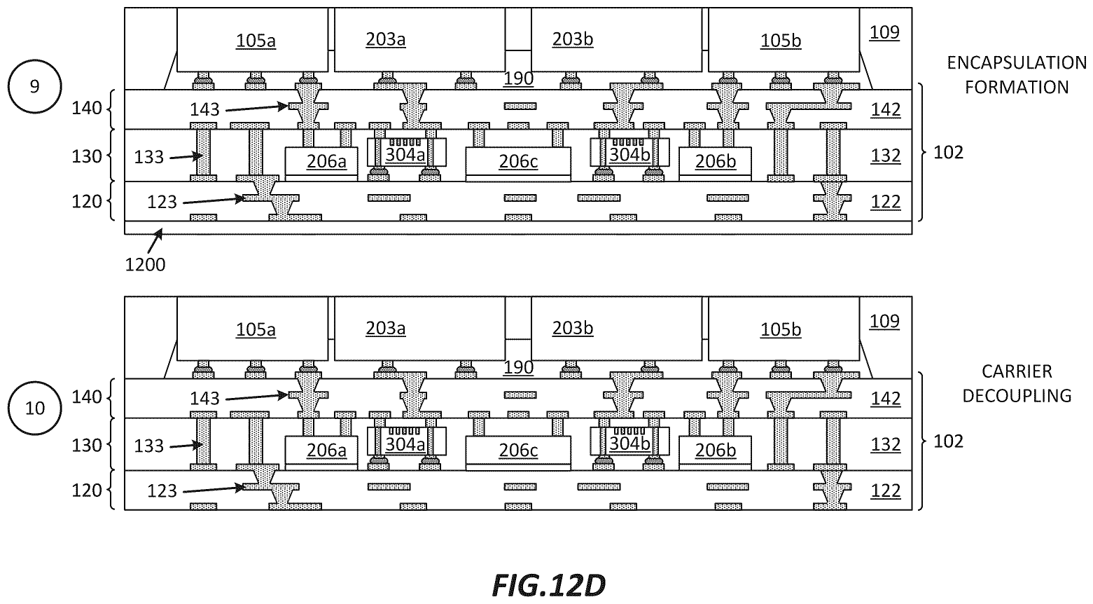

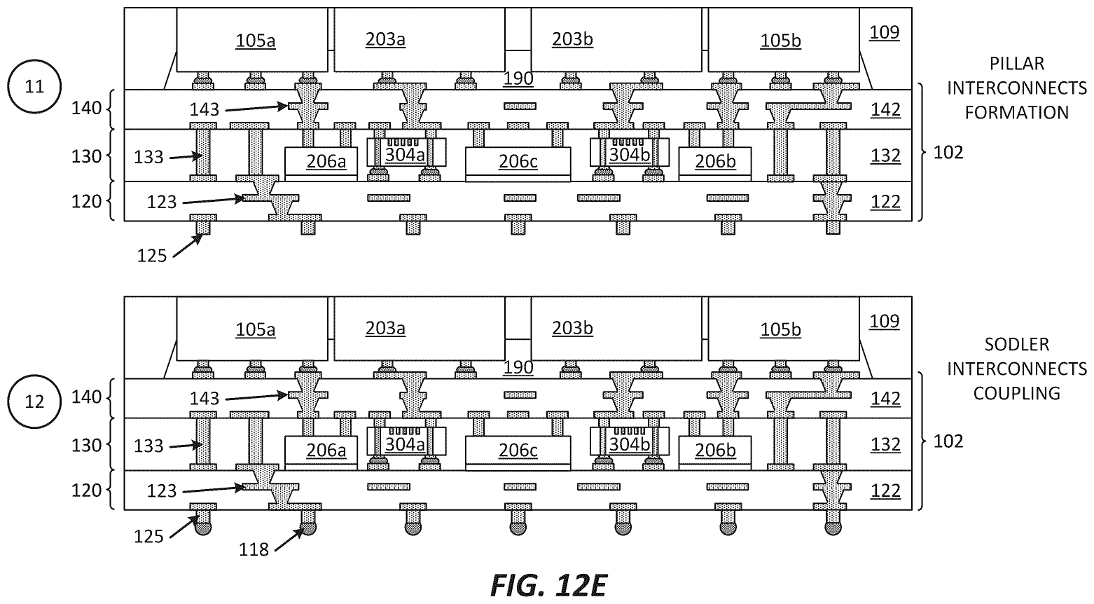

In some implementations, fabricating a package includes several processes. FIGS. 12A-12E illustrate an exemplary sequence for providing or fabricating a package. In some implementations, the sequence of FIGS. 12A-12E may be used to provide or fabricate the package 300. However, the process of FIGS. 12A-12E may be used to fabricate any of the packages (e.g., 200) described in the disclosure.

It should be noted that the sequence of FIGS. 12A-12E may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1 of FIG. 12A, illustrates a state after a carrier 1200 and a metallization portion 120 is formed on the carrier 1200. The carrier 1200 may include a glass carrier.

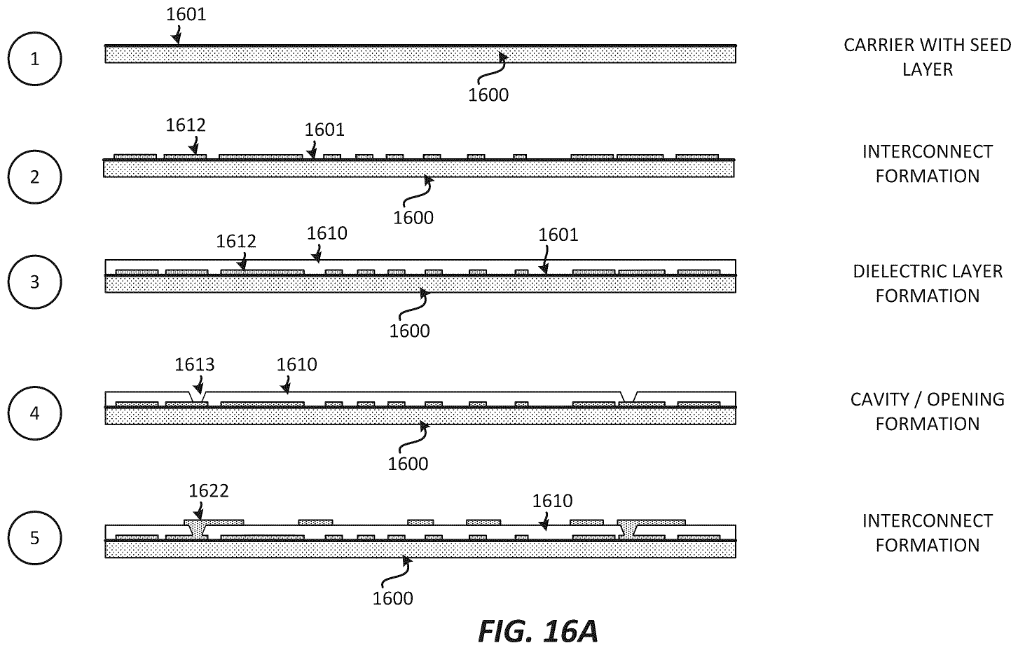

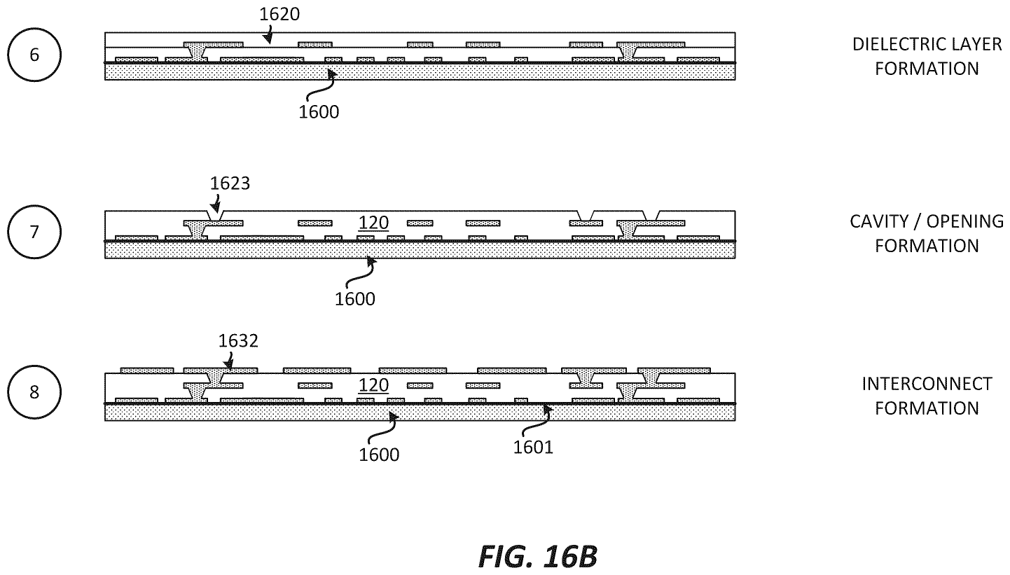

The metallization portion 120 includes at least one dielectric layer 122 and a plurality of metallization interconnects 123. In some implementations, the metallization portion 120 may be a first metallization portion. In some implementations, the at least one dielectric layer 122 may be an at least first dielectric layer. In some implementations, the plurality of metallization interconnects 123 may be a first plurality of metallization interconnects. The metallization portion 120 may be fabricated using the method as described in FIGS. 16A-16B.

Stage 2 of FIG. 12A, illustrates a state after a plurality of post interconnects 133 are formed and coupled to the metallization portion 120. The plurality of post interconnects 133 may be coupled to the plurality of metallization interconnects 123. A lithography process, a plating process, a strip process and/or an etching process may be used to form the plurality of post interconnects 133. In some implementations, the metallization portion 120 may be optional. In such instances, the plurality of post interconnects 133 may be formed and coupled to the carrier 1200.

Stage 3 of FIG. 12A, illustrates a state after a bridge 206a, a bridge 206b, a bridge 206c to the metallization portion 120. A back side of the bridge 206a is coupled metallization portion 120 through an adhesive 260a. A back side of the bridge 206b is coupled metallization portion 120 through an adhesive 260b. A back side of the bridge 206c is coupled metallization portion 120 through an adhesive 260c. The bridge 206a may include the plurality of post interconnects 265a. The bridge 206b may include the plurality of post interconnects 265b. The bridge 206c may include the plurality of post interconnects 265c. The back side of a bridge (e.g., silicon bridge) may be a side that includes a bridge substrate (e.g., silicon bridge substrate). The front side of a bridge may be a side that includes a bridge interconnect and/or a bridge dielectric layer.

Stage 3 of FIG. 12A, also illustrates a state after a passive device 304a and a passive device 304b are coupled to the metallization portion 120. A back side of the passive device 304a may be coupled to metallization portion 120 through a plurality of solder interconnects 340a. A back side of the passive device 304b may be coupled to metallization portion 120 through a plurality of solder interconnects 340b. The passive device 304a may include the plurality of post interconnects 345a. The passive device 304b may include the plurality of post interconnects 345b.

Stage 4 of FIG. 12B, illustrates a state after an encapsulation layer 132 is formed and coupled to the metallization portion 120. The encapsulation layer 132 may be a first encapsulation layer. The encapsulation layer 132 may include a mold, a resin and/or an epoxy. The encapsulation layer 132 may be a means for encapsulation. The encapsulation layer 132 may be provided by using a compression and transfer molding process, a sheet molding process, or a liquid molding process. The encapsulation layer 132 may at least partially encapsulate the plurality of post interconnects 133, the bridge 206a, the bridge 206b, the bridge 206c, the passive device 304a and/or the passive device 304b, the plurality of post interconnects 265a, the plurality of post interconnects 265b, the plurality of post interconnects 265c, the plurality of post interconnects 345a and/or the plurality of post interconnects 345b. The encapsulation layer 132 may be over molded.

Stage 5 of FIG. 12B, illustrates a state a portion of the encapsulation layer 132 is removed. The encapsulation layer 132 may be grinded to form an encapsulation layer 132 with a planar surface. Portions of the plurality of post interconnects 133 and/or other post interconnects may also be removed. Stage 5 of FIG. 12B, may illustrate the encapsulated portion 130 that is coupled to the metallization portion 120.

Stage 6 of FIG. 12B, illustrates a state after a metallization portion 140 is formed over and coupled to the encapsulated portion 130. The metallization portion 140 may be formed over the encapsulation layer 132. The metallization portion 140 includes at least one dielectric layer 142 and a plurality of metallization interconnects 143. In some implementations, the metallization portion 140 may be a second metallization portion. In some implementations, the at least one dielectric layer 142 may be an at least second dielectric layer. In some implementations, the plurality of metallization interconnects 143 may be a second plurality of metallization interconnects. The metallization portion 140 may be fabricated using the method as described in FIGS. 16A-16B. The plurality of metallization interconnects 143 may be coupled to the plurality of post interconnects 133 and/or other post interconnects in the encapsulation layer 132. Stage 6 may illustrate a package interposer 102 that includes the metallization portion 120, the encapsulated portion 130 and the metallization portion 140. The encapsulated portion 130 may be located between the metallization portion 120 and the metallization portion 140.

Stage 7 of FIG. 12C, illustrates a state after integrated devices are coupled to the package interposer 102. The integrated device 203a is coupled to the metallization portion 140 through a plurality of pillar interconnects 230a and a plurality of solder interconnects 232a. A solder reflow process may be used to couple the integrated device 203a. The integrated device 203b is coupled to the metallization portion 140 through a plurality of pillar interconnects 230b and a plurality of solder interconnects 232b. A solder reflow process may be used to couple the integrated device 203b.

The integrated device 105a is coupled to the metallization portion 140 through a plurality of pillar interconnects 150a and a plurality of solder interconnects 152a. A solder reflow process may be used to couple the integrated device 105a. The integrated device 105b is coupled to the metallization portion 140 through a plurality of pillar interconnects 150b and a plurality of solder interconnects 152b. A solder reflow process may be used to couple the integrated device 105b.

Stage 8 of FIG. 12C, illustrates a state after an underfill 190 is provided. The underfill 190 may be disposed on the package interposer 102. The underfill 190 may be located between the metallization portion 140 and the integrated device 203a, the integrated device 203b, the integrated device 105a, the integrated device 105b and the integrated device 105c. In some implementations, the underfill 190 may include a composite material comprising an epoxy polymer with filler.

Stage 9 of FIG. 12D, illustrates a state an encapsulation layer 109 is formed and coupled to the package interposer 102. The encapsulation layer 109 is coupled to the metallization portion 140. The encapsulation layer 109 may include a mold, a resin and/or an epoxy. The encapsulation layer 109 may be a means for encapsulation. The encapsulation layer 109 may be provided by using a compression and transfer molding process, a sheet molding process, or a liquid molding process. The encapsulation layer 109 may include a different material and/or a different composition from the underfill 190.

Stage 10 of FIG. 12D, illustrates a state after the package interposer 102 is decoupled from the carrier 1200. The package interposer 102 may be detached from the carrier 1200.

Stage 11 of FIG. 12E, illustrates a state after a plurality of pillar interconnects 125 are formed and coupled to the metallization portion 120. The plurality of pillar interconnects 125 may be coupled to the plurality of metallization interconnects 123. A lithography process, a plating process, a strip process and/or an etching process may be used to form the plurality of pillar interconnects 125. The plurality of pillar interconnects 125 may be optional.

Stage 12 of FIG. 12E, illustrates a state after a plurality of solder interconnects 118 are coupled to the plurality of pillar interconnects 125. A solder reflow process may be used to couple the plurality of pillar interconnects 125. In some implementations, the plurality of solder interconnects 118 may be coupled to the plurality of metallization interconnects 123. Stage 12 of FIG. 12E may illustrate a package 300.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Package Comprising a Package Interposer and a Passive Device and a Bridge Located at Least Partially in the Package Interposer

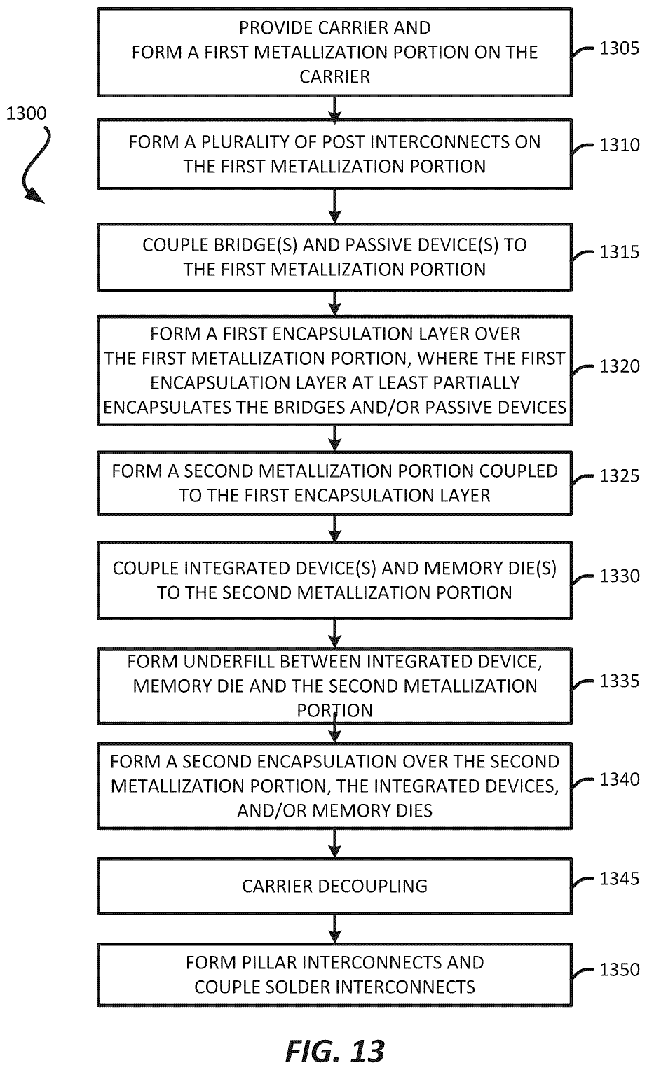

In some implementations, fabricating a package includes several processes. FIG. 13 illustrates an exemplary flow diagram of a method 1300 for providing or fabricating a package. In some implementations, the method 1300 of FIG. 13 may be used to provide or fabricate the package 300 described in the disclosure. However, the method 1300 may be used to provide or fabricate any of the packages (e.g., 200) described in the disclosure.

It should be noted that the method 1300 of FIG. 13 may combine one or more processes in order to simplify and/or clarify the method for providing or fabricating a package. In some implementations, the order of the processes may be changed or modified.

The method provides (at 1305) a carrier and forms a first metallization portion on the carrier. substrate. Stage 1 of FIG. 12A, illustrates and described an example of a state after a carrier 1200 and a metallization portion 120 is formed on the carrier 1200. The carrier 1200 may include a glass carrier. The metallization portion 120 includes at least one dielectric layer 122 and a plurality of metallization interconnects 123. In some implementations, the metallization portion 120 may be a first metallization portion. In some implementations, the at least one dielectric layer 122 may be an at least first dielectric layer. In some implementations, the plurality of metallization interconnects 123 may be a first plurality of metallization interconnects. The metallization portion 120 may be fabricated using the method as described in FIGS. 16A-16B.

The method forms (at 1310) a plurality of post interconnects on the first metallization portion. Stage 2 of FIG. 12A, illustrates and described an example of a state after a plurality of post interconnects 133 are formed and coupled to the metallization portion 120. The plurality of post interconnects 133 may be coupled to the plurality of metallization interconnects 123. A lithography process, a plating process, a strip process and/or an etching process may be used to form the plurality of post interconnects 133. In some implementations, the metallization portion 120 may be optional. In such instances, the plurality of post interconnects 133 may be formed and coupled to the carrier 1200.

The method couples (at 1315) at least one bridge and/or at least one passive device to the first metallization portion. Stage 3 of FIG. 12A, illustrates and described an example of a state after a bridge 206a, a bridge 206b, a bridge 206c to the metallization portion 120. A back side of the bridge 206a is coupled metallization portion 120 through an adhesive 260a. A back side of the bridge 206b is coupled metallization portion 120 through an adhesive 260b. A back side of the bridge 206c is coupled metallization portion 120 through an adhesive 260c. The bridge 206a may include the plurality of post interconnects 265a. The bridge 206b may include the plurality of post interconnects 265b. The bridge 206c may include the plurality of post interconnects 265c.

Stage 3 of FIG. 12A, also illustrates a state after a passive device 304a and a passive device 304b are coupled to the metallization portion 120. A back side of the passive device 304a may be coupled to metallization portion 120 through a plurality of solder interconnects 340a. A back side of the passive device 304b may be coupled to metallization portion 120 through a plurality of solder interconnects 340b. The passive device 304a may include the plurality of post interconnects 345a. The passive device 304b may include the plurality of post interconnects 345b.

The method forms (at 1320) a first encapsulation layer over the first metallization portion. Stage 4 of FIG. 12B, illustrates and describes an example of a state after an encapsulation layer 132 is formed and coupled to the metallization portion 120. The encapsulation layer 132 may be a first encapsulation layer. The encapsulation layer 132 may include a mold, a resin and/or an epoxy. The encapsulation layer 132 may be a means for encapsulation. The encapsulation layer 132 may be provided by using a compression and transfer molding process, a sheet molding process, or a liquid molding process. The encapsulation layer 132 may at least partially encapsulate the plurality of post interconnects 133, the bridge 206a, the bridge 206b, the bridge 206c, the passive device 304a and/or the passive device 304b, the plurality of post interconnects 265a, the plurality of post interconnects 265b, the plurality of post interconnects 265c, the plurality of post interconnects 345a and/or the plurality of post interconnects 345b The encapsulation layer 132 may be over molded.

In some implementations, forming the first encapsulation layer may include removing and/or grinding portions of the first encapsulation layer. Stage 5 of FIG. 12B, illustrates a state a portion of the encapsulation layer 132 is removed. The encapsulation layer 132 may be grinded to form an encapsulation layer 132 with a planar surface. Portions of the plurality of post interconnects 133 and/or other post interconnects may also be removed. Stage 5 of FIG. 12B, may illustrate the encapsulated portion 130 that is coupled to the metallization portion 120.

The method forms (at 1325) a second metallization portion that is coupled to the first encapsulation layer. Stage 6 of FIG. 12B, illustrates and describes an example of a state after a metallization portion 140 is formed over and coupled to the encapsulated portion 130. The metallization portion 140 may be formed over the encapsulation layer 132. The metallization portion 140 includes at least one dielectric layer 142 and a plurality of metallization interconnects 143. In some implementations, the metallization portion 140 may be a second metallization portion. In some implementations, the at least one dielectric layer 142 may be an at least second dielectric layer. In some implementations, the plurality of metallization interconnects 143 may be a second plurality of metallization interconnects. The metallization portion 140 may be fabricated using the method as described in FIGS. 16A-16B. The plurality of metallization interconnects 143 may be coupled to the plurality of post interconnects 133 and/or other post interconnects in the encapsulation layer 132. Stage 6 may illustrate a package interposer 102 that includes the metallization portion 120, the encapsulated portion 130 and the metallization portion 140. The encapsulated portion 130 may be located between the metallization portion 120 and the metallization portion 140.

The method couples (at 1330) at least one integrated device to the second metallization portion. Stage 7 of FIG. 12C, illustrates and describes an example of a state after integrated devices are coupled to the package interposer 102. The integrated device 203a is coupled to the metallization portion 140 through a plurality of pillar interconnects 230a and a plurality of solder interconnects 232a. A solder reflow process may be used to couple the integrated device 203a. The integrated device 203b is coupled to the metallization portion 140 through a plurality of pillar interconnects 230b and a plurality of solder interconnects 232b. A solder reflow process may be used to couple the integrated device 203b.

The integrated device 105a is coupled to the metallization portion 140 through a plurality of pillar interconnects 150a and a plurality of solder interconnects 152a. A solder reflow process may be used to couple the integrated device 105a. The integrated device 105b is coupled to the metallization portion 140 through a plurality of pillar interconnects 150b and a plurality of solder interconnects 152b. A solder reflow process may be used to couple the integrated device 105b.

The method forms (at 1335) an underfill. Stage 8 of FIG. 12C, illustrates and describes an example of a state after an underfill 190 is provided. The underfill 190 may be disposed on the package interposer 102. The underfill 190 may be located between the metallization portion 140 and the integrated device 203a, the integrated device 203b, the integrated device 105a, the integrated device 105b and the integrated device 105c. In some implementations, the underfill 190 may include a composite material comprising an epoxy polymer with filler.

The method forms (at 1340) a second encapsulation layer that is coupled to the second metallization portion of the package interposer. Stage 9 of FIG. 12D, illustrates and describes an example of a state an encapsulation layer 109 is formed and coupled to the package interposer 102. The encapsulation layer 109 is coupled to the metallization portion 140. The encapsulation layer 109 may include a mold, a resin and/or an epoxy. The encapsulation layer 109 may be a means for encapsulation. The encapsulation layer 109 may be provided by using a compression and transfer molding process, a sheet molding process, or a liquid molding process. The encapsulation layer 109 may include a different material and/or a different composition from the underfill 190.

The method decouples (at 1345) the carrier from the package interposer. Stage 10 of FIG. 12D, illustrates and describes an example of a state after the package interposer 102 is decoupled from the carrier 1200. The package interposer 102 may be detached from the carrier 1200.

The method forms (at 1350) a plurality of pillar interconnects and couples (at 1350) a plurality of solder interconnects to the plurality of pillar interconnects. Stage 11 of FIG. 12E, illustrates a state after a plurality of pillar interconnects 125 are formed and coupled to the metallization portion 120. The plurality of pillar interconnects 125 may be coupled to the plurality of metallization interconnects 123. A lithography process, a plating process, a strip process and/or an etching process may be used to form the plurality of pillar interconnects 125. The plurality of pillar interconnects 125 may be optional.

Stage 12 of FIG. 12E, illustrates a state after a plurality of solder interconnects 118 are coupled to the plurality of pillar interconnects 125. A solder reflow process may be used to couple the plurality of pillar interconnects 125. In some implementations, the plurality of solder interconnects 118 may be coupled to the plurality of metallization interconnects 123. Stage 12 of FIG. 12E may illustrate a package 300.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Sequence for Fabricating a Package Comprising a Package Interposer and a Passive Device and a Bridge Located at Least Partially in the Package Interposer

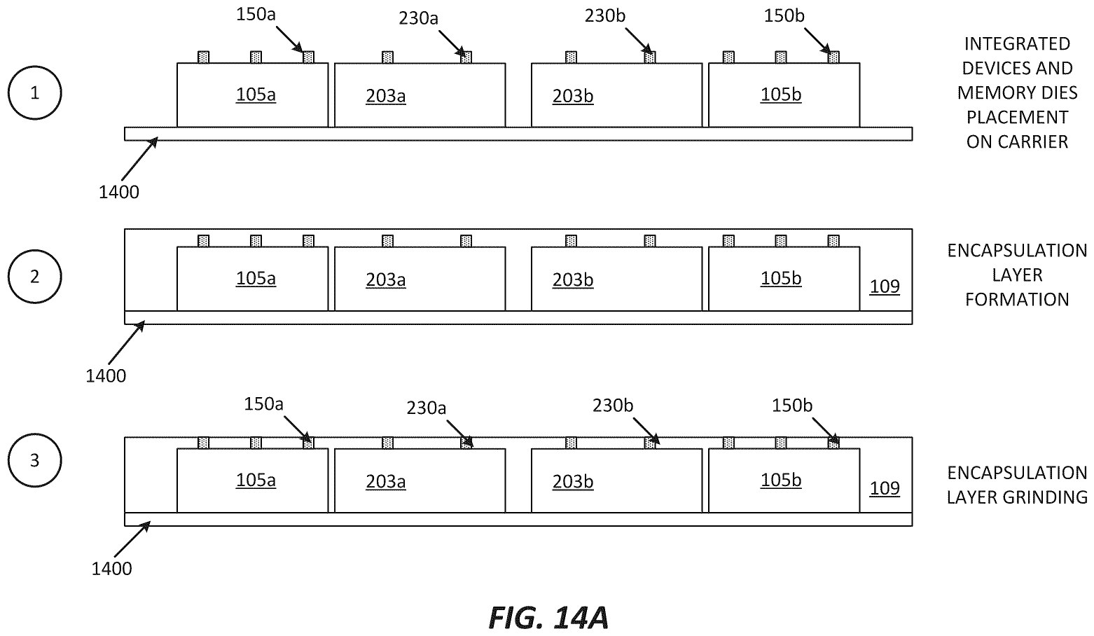

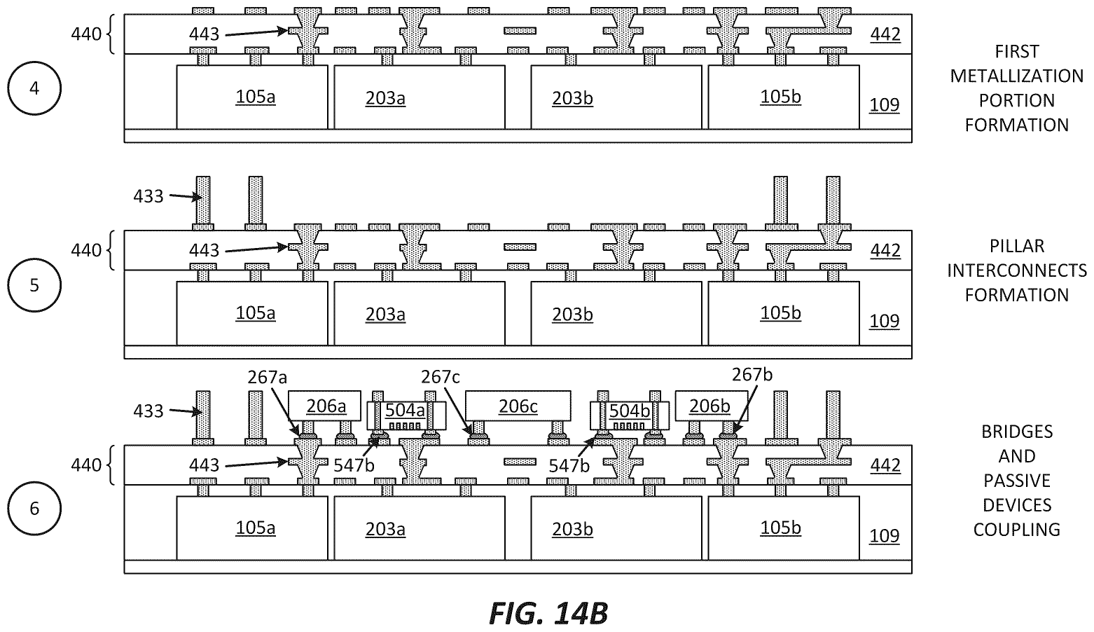

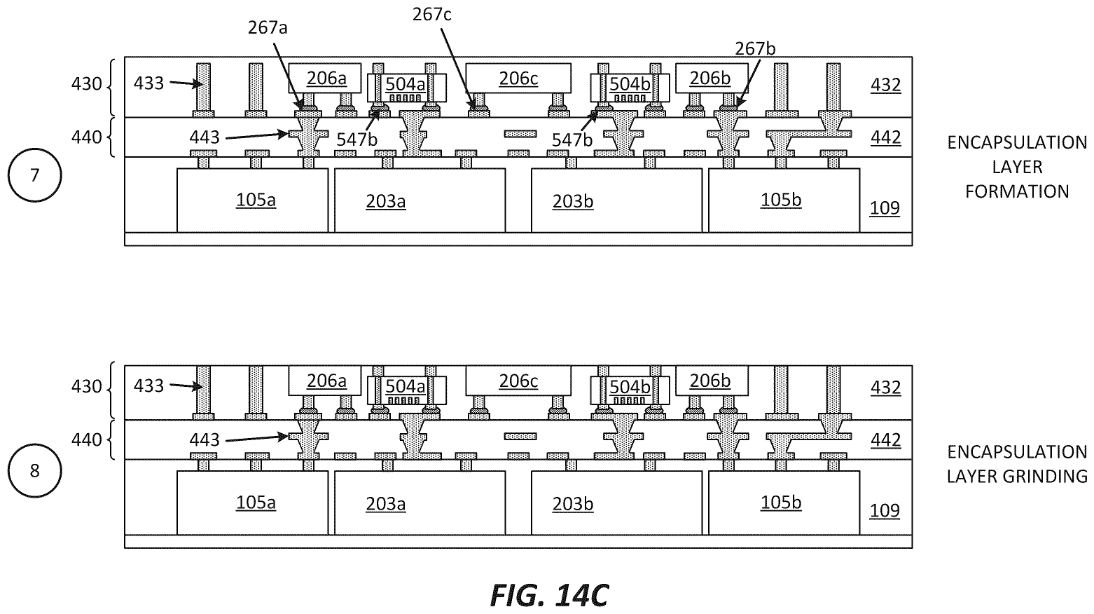

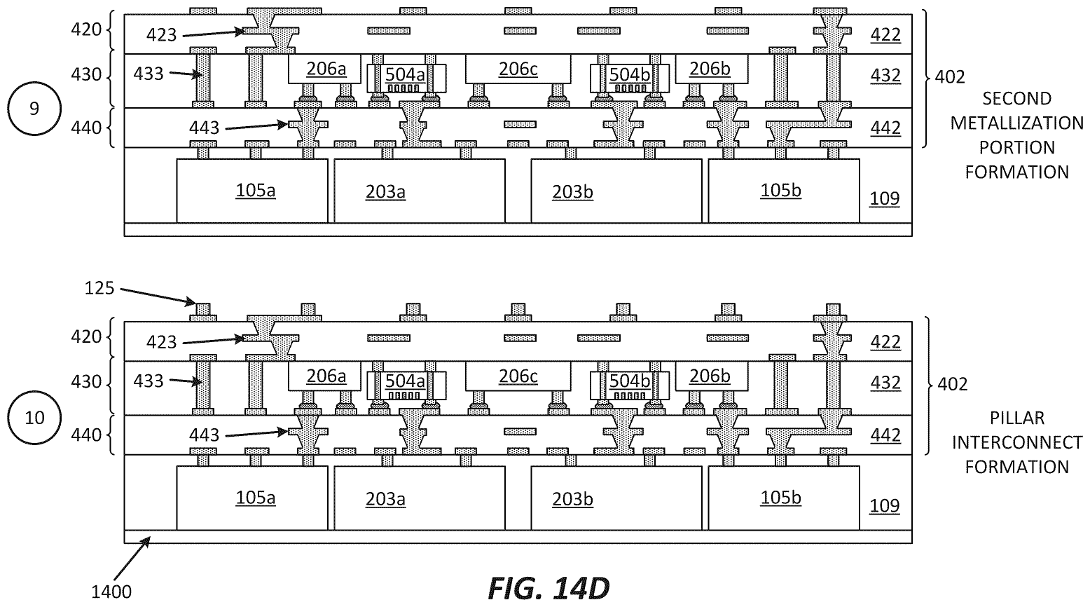

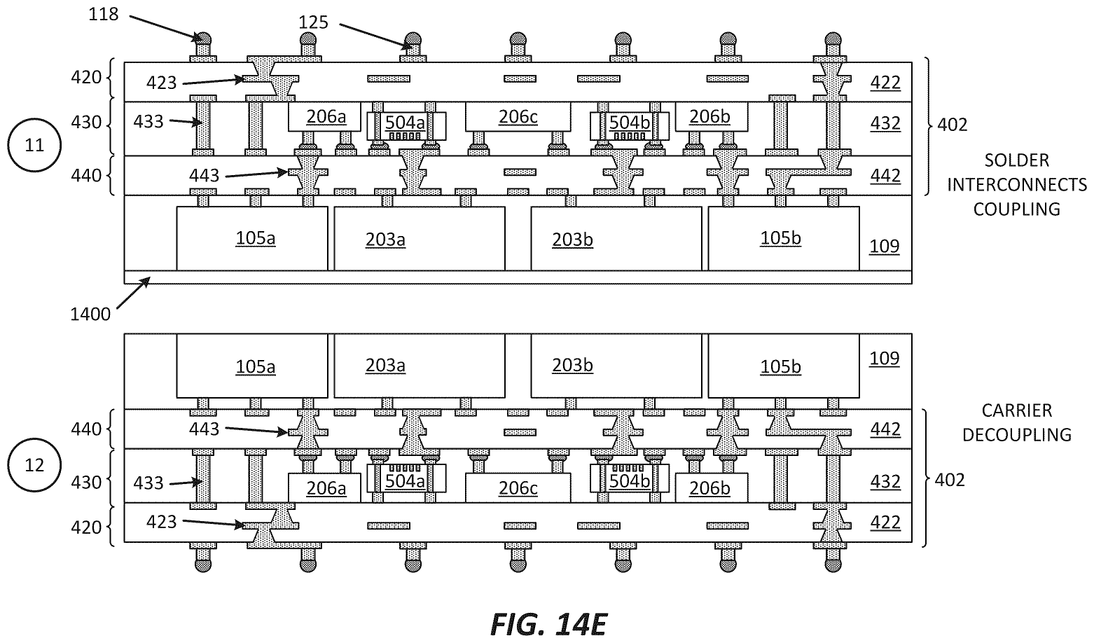

In some implementations, fabricating a package includes several processes. FIGS. 14A-14E illustrate an exemplary sequence for providing or fabricating a package. In some implementations, the sequence of FIGS. 14A-14E may be used to provide or fabricate the package 500. However, the process of FIGS. 14A-14E may be used to fabricate any of the packages (e.g., 400) described in the disclosure.

It should be noted that the sequence of FIGS. 14A-14E may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1 of FIG. 14A, illustrates a state after a carrier 1400 and a plurality of integrated devices is placed on the carrier 1400. The plurality of integrated devices may be coupled to the carrier 1400 through one or more adhesives. A back side of the integrated device 203a is placed and/or coupled to the carrier 1400. A back side of the integrated device 203b is placed and/or coupled to the carrier 1400. A back side of the integrated device 105a is placed and/or coupled to the carrier 1400. A back side of the integrated device 105b is placed and/or coupled to the carrier 1400.

Stage 2 of FIG. 14A, illustrates a state an encapsulation layer 109 is formed and coupled to the carrier 1400, the integrated device 105a, the integrated device 105b, the integrated device 203a and the integrated device 203b. The encapsulation layer 109 may include a mold, a resin and/or an epoxy. The encapsulation layer 109 may be a means for encapsulation. The encapsulation layer 109 may be provided by using a compression and transfer molding process, a sheet molding process, or a liquid molding process. The encapsulation layer 109 may be over molded. The encapsulation layer 109 may at least partially encapsulate the integrated device 105a, the integrated device 105b, the integrated device 203a, the integrated device 203b, the plurality of pillar interconnects 150a, the plurality of pillar interconnects 150b, the plurality of pillar interconnects 230a and/or the plurality of pillar interconnects 230b.

Stage 3 of FIG. 14A, illustrates a state after portions of the encapsulation layer 109 are removed. A grinding process may be used remove portions of the encapsulation layer 109. In some implementations, portions of pillar interconnects coupled to and/or part of the integrated device 105a, the integrated device 105b, the integrated device 203a and/or the integrated device 203b may also be removed.

Stage 4 of FIG. 14B, illustrates a state a metallization portion 440 is formed and coupled to the encapsulation layer 109. The metallization portion 440 includes at least one dielectric layer 442 and a plurality of metallization interconnects 443. In some implementations, the metallization portion 440 may be a first metallization portion. In some implementations, the at least one dielectric layer 442 may be an at least first dielectric layer. In some implementations, the plurality of metallization interconnects 443 may be a first plurality of metallization interconnects. The metallization portion 440 may be fabricated using the method as described in FIGS. 16A-16B.

Stage 5 of FIG. 14B, illustrates a state after a plurality of post interconnects 433 are formed and coupled to the metallization portion 440. The plurality of post interconnects 433 may be coupled to the plurality of metallization interconnects 443. A lithography process, a plating process, a strip process and/or an etching process may be used to form the plurality of post interconnects 433.

Stage 6 of FIG. 14B, illustrates a state after a bridge 206a, a bridge 206b, a bridge 206c are coupled to the metallization portion 120. A front side of the bridge 206a is coupled to the metallization portion 440 through a plurality of solder interconnects 267a. A front side of the bridge 206b is coupled metallization portion 440 through a plurality of solder interconnects 267b. A front side of the bridge 206c is coupled metallization portion 440 through a plurality of solder interconnects 267c. A bridge may include a front side and a back side. The back side of a bridge (e.g., silicon bridge) may be a side that includes a bridge substrate (e.g., silicon bridge substrate). The front side of a bridge may be a side that includes a bridge interconnect and/or a bridge dielectric layer.

Stage 6 of FIG. 14B, also illustrates a state after a passive device 504a and a passive device 504b are coupled to the metallization portion 440. A front side of the passive device 504a may be coupled to metallization portion 440 through a plurality of solder interconnects 547a. A front side of the passive device 504b may be coupled to metallization portion 440 through a plurality of solder interconnects 547b.

Stage 7 of FIG. 14C, illustrates a state after an encapsulation layer 432 is formed and coupled to the metallization portion 440. The encapsulation layer 432 may be a second encapsulation layer. The encapsulation layer 432 may include a mold, a resin and/or an epoxy. The encapsulation layer 432 may be a means for encapsulation. The encapsulation layer 432 may be provided by using a compression and transfer molding process, a sheet molding process, or a liquid molding process. The encapsulation layer 432 may at least partially encapsulate the plurality of post interconnects 433, the bridge 206a, the bridge 206b, the bridge 206c, the passive device 504a and/or the passive device 504b. The encapsulation layer 432 may be over molded. The encapsulation layer 432 may at least partially encapsulate the plurality of post interconnects 265a, the plurality of post interconnects 265b, the plurality of post interconnects 265c, the plurality of post interconnects 549a, the plurality of post interconnects 549b, the plurality of solder interconnects 267a, the plurality of solder interconnects 267b, the plurality of solder interconnects 267c, the plurality of solder interconnects 547a and/or, the plurality of solder interconnects 547b.

Stage 8 of FIG. 14C, illustrates a state a portion of the encapsulation layer 432 is removed. The encapsulation layer 432 may be grinded to form an encapsulation layer 432 with a planar surface. Portions of the plurality of post interconnects 433 and/or other post interconnects may also be removed. Stage 8 may illustrates an encapsulated portion 430 that includes an encapsulation layer 432, a plurality of post interconnects 433, at least one bridge and at least one passive device. Stage 8 of FIG. 14C, illustrates an encapsulated portion 430 that is coupled to the metallization portion 440.

Stage 9 of FIG. 14D, illustrates a state after a metallization portion 420 is formed over and coupled to the encapsulated portion 430. The metallization portion 420 may be formed over the encapsulation layer 432. The metallization portion 420 includes at least one dielectric layer 422 and a plurality of metallization interconnects 423. In some implementations, the metallization portion 420 may be a second metallization portion. In some implementations, the at least one dielectric layer 422 may be an at least second dielectric layer. In some implementations, the plurality of metallization interconnects 423 may be a second plurality of metallization interconnects. The metallization portion 420 may be fabricated using the method as described in FIGS. 16A-16B. The plurality of metallization interconnects 423 may be coupled to the plurality of post interconnects 433 and/or other post interconnects in the encapsulation layer 432. Stage 9 may illustrate a package interposer 402 that includes the metallization portion 420, the encapsulated portion 430 and the metallization portion 440. The encapsulated portion 430 may be located between the metallization portion 420 and the metallization portion 440.

Stage 10 of FIG. 14D, illustrates a state after a plurality of pillar interconnects 125 are formed and coupled to the metallization portion 420. The plurality of pillar interconnects 125 may be coupled to the plurality of metallization interconnects 423. A lithography process, a plating process, a strip process and/or an etching process may be used to form the plurality of pillar interconnects 125. The plurality of pillar interconnects 125 may be optional. In some implementations, the metallization portion 420 may be optional. In such instances, the plurality of pillar interconnects 125 may be formed and coupled to the plurality of post interconnects 433.

Stage 11 of FIG. 14E, illustrates a state after a plurality of solder interconnects 118 are coupled to the plurality of pillar interconnects 125. A solder reflow process may be used to couple the plurality of pillar interconnects 125. In some implementations, the plurality of solder interconnects 118 may be coupled to the plurality of metallization interconnects 423.

Stage 12 of FIG. 14E, illustrates a state after the package interposer 402 is decoupled from the carrier 1400. The package interposer 402 may be detached from the carrier 1400. Stage 12 of FIG. 14E may illustrate a package 500.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Package Comprising a Package Interposer and a Passive Device and a Bridge Located at Least Partially in the Package Interposer

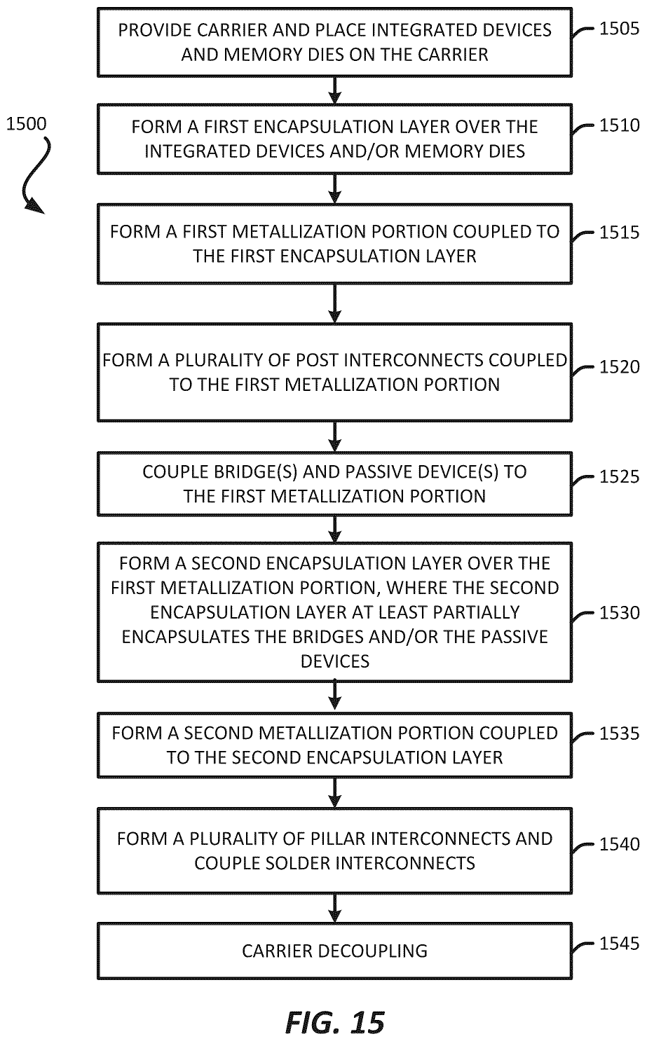

In some implementations, fabricating a package includes several processes. FIG. 15 illustrates an exemplary flow diagram of a method 1500 for providing or fabricating a package. In some implementations, the method 1500 of FIG. 15 may be used to provide or fabricate the package 500 described in the disclosure. However, the method 1500 may be used to provide or fabricate any of the packages (e.g., 400) described in the disclosure.

It should be noted that the method 1500 of FIG. 15 may combine one or more processes in order to simplify and/or clarify the method for providing or fabricating a package. In some implementations, the order of the processes may be changed or modified.

The method provides (at 1505) a carrier and places (at 1505) integrated devices on the carrier. Stage 1 of FIG. 14A, illustrates and describes an example of a state after a carrier 1400 and a plurality of integrated devices is placed on the carrier 1400. The plurality of integrated devices may be coupled to the carrier 1400 through one or more adhesives. A back side of the integrated device 203a is placed and/or coupled to the carrier 1400. A back side of the integrated device 203b is placed and/or coupled to the carrier 1400. A back side of the integrated device 105a is placed and/or coupled to the carrier 1400. A back side of the integrated device 105b is placed and/or coupled to the carrier 1400.

The method forms (at 1510) a first encapsulation layer over the carrier and the integrated devices. Stage 2 of FIG. 14A, illustrates and describes an example of a state an encapsulation layer 109 is formed and coupled to the carrier 1400, the integrated device 105a, the integrated device 105b, the integrated device 203a and the integrated device 203b. The encapsulation layer 109 may include a mold, a resin and/or an epoxy. The encapsulation layer 109 may be a means for encapsulation. The encapsulation layer 109 may be provided by using a compression and transfer molding process, a sheet molding process, or a liquid molding process. The encapsulation layer 109 may be over molded. The encapsulation layer 109 may at least partially encapsulate the integrated device 105a, the integrated device 105b, the integrated device 203a, the integrated device 203b, the plurality of pillar interconnects 150a, the plurality of pillar interconnects 150b, the plurality of pillar interconnects 230a and/or the plurality of pillar interconnects 230b.

In some implementations, forming the first encapsulation layer may include removing portions of the first encapsulation layer. Stage 3 of FIG. 14A, illustrates and describes an example of a state after portions of the encapsulation layer 109 are removed. A grinding process may be used remove portions of the encapsulation layer 109. In some implementations, portions of pillar interconnects coupled to and/or part of the integrated device 105a, the integrated device 105b, the integrated device 203a and/or the integrated device 203b may also be removed.

The method forms (at 1515) a first metallization portion that is coupled to the first encapsulation layer. Stage 4 of FIG. 14B, illustrates and describes an example of a state a metallization portion 440 is formed and coupled to the encapsulation layer 109. The metallization portion 440 includes at least one dielectric layer 442 and a plurality of metallization interconnects 443. In some implementations, the metallization portion 440 may be a first metallization portion. In some implementations, the at least one dielectric layer 442 may be an at least first dielectric layer. In some implementations, the plurality of metallization interconnects 443 may be a first plurality of metallization interconnects. The metallization portion 440 may be fabricated using the method as described in FIGS. 16A-16B.

The method forms (at 1520) a plurality of post interconnects that are coupled to the first metallization portion. Stage 5 of FIG. 14B, illustrates and describes an example of a state after a plurality of post interconnects 433 are formed and coupled to the metallization portion 440. The plurality of post interconnects 433 may be coupled to the plurality of metallization interconnects 443. A lithography process, a plating process, a strip process and/or an etching process may be used to form the plurality of post interconnects 433.

The method couples (at 1520) at least one bridge and/or at least one passive device to the first metallization portion. Stage 6 of FIG. 14B, illustrates and describes an example of a state after a bridge 206a, a bridge 206b, a bridge 206c are coupled to the metallization portion 120. A front side of the bridge 206a is coupled metallization portion 440 through a plurality of solder interconnects 267a. A front side of the bridge 206b is coupled metallization portion 440 through a plurality of solder interconnects 267b. A front side of the bridge 206c is coupled metallization portion 440 through a plurality of solder interconnects 267c.

Stage 6 of FIG. 14B, also illustrates and describes an example of a state after a passive device 504a and a passive device 504b are coupled to the metallization portion 440. A front side of the passive device 504a may be coupled to metallization portion 440 through a plurality of solder interconnects 547a. A front side of the passive device 504b may be coupled to metallization portion 440 through a plurality of solder interconnects 547b.

The method forms (at 1530) a second encapsulation layer that is coupled to the first metallization portion. Stage 7 of FIG. 14C, illustrates and describes an example of a state after an encapsulation layer 432 is formed and coupled to the metallization portion 440. The encapsulation layer 432 may be a second encapsulation layer. The encapsulation layer 432 may include a mold, a resin and/or an epoxy. The encapsulation layer 432 may be a means for encapsulation. The encapsulation layer 432 may be provided by using a compression and transfer molding process, a sheet molding process, or a liquid molding process. The encapsulation layer 432 may at least partially encapsulate the plurality of post interconnects 433, the bridge 206a, the bridge 206b, the bridge 206c, the passive device 504a and/or the passive device 504b. The encapsulation layer 432 may be over molded. The encapsulation layer 432 may at least partially encapsulate the plurality of post interconnects 265a, the plurality of post interconnects 265b, the plurality of post interconnects 265c, the plurality of post interconnects 549a, the plurality of post interconnects 549b, the plurality of solder interconnects 267a, the plurality of solder interconnects 267b, the plurality of solder interconnects 267c, the plurality of solder interconnects 547a and/or, the plurality of solder interconnects 547b.

In some implementations, forming the second encapsulation layer may include removing portions of the second encapsulation layer. Stage 8 of FIG. 14C, illustrates and describes an example of a state a portion of the encapsulation layer 432 is removed. The encapsulation layer 432 may be grinded to form an encapsulation layer 432 with a planar surface. Portions of the plurality of post interconnects 433 and/or other post interconnects may also be removed. Stage 8 may illustrates an encapsulated portion 430 that includes an encapsulation layer 432, a plurality of post interconnects 433, at least one bridge and at least one passive device. Stage 8 of FIG. 14C, illustrates an encapsulated portion 430 that is coupled to the metallization portion 440.

The method forms (at 1535) a second metallization portion that is coupled to the second encapsulation layer. Stage 9 of FIG. 14D, illustrates and describes an example of a state after a metallization portion 420 is formed over and coupled to the encapsulated portion 430. The metallization portion 420 may be formed over the encapsulation layer 432. The metallization portion 420 includes at least one dielectric layer 422 and a plurality of metallization interconnects 423. In some implementations, the metallization portion 420 may be a second metallization portion. In some implementations, the at least one dielectric layer 422 may be an at least second dielectric layer. In some implementations, the plurality of metallization interconnects 423 may be a second plurality of metallization interconnects. The metallization portion 420 may be fabricated using the method as described in FIGS. 16A-16B. The plurality of metallization interconnects 423 may be coupled to the plurality of post interconnects 433 and/or other post interconnects in the encapsulation layer 432. Stage 9 may illustrate a package interposer 402 that includes the metallization portion 420, the encapsulated portion 430 and the metallization portion 440. The encapsulated portion 430 may be located between the metallization portion 420 and the metallization portion 440.

The method forms (at 1540) a plurality of pillar interconnects and couples (at 1540) a plurality of solder interconnects to the plurality of pillar interconnects. Stage 10 of FIG. 14D, illustrates and describes an example of a state after a plurality of pillar interconnects 125 are formed and coupled to the metallization portion 420. The plurality of pillar interconnects 125 may be coupled to the plurality of metallization interconnects 423. A lithography process, a plating process, a strip process and/or an etching process may be used to form the plurality of pillar interconnects 125. The plurality of pillar interconnects 125 may be optional. In some implementations, the metallization portion 420 may be optional. In such instances, the plurality of pillar interconnects 125 may be formed and coupled to the plurality of post interconnects 433.

Stage 11 of FIG. 14E, illustrates and describes an example of a state after a plurality of solder interconnects 118 are coupled to the plurality of pillar interconnects 125. A solder reflow process may be used to couple the plurality of pillar interconnects 125. In some implementations, the plurality of solder interconnects 118 may be coupled to the plurality of metallization interconnects 423.

The method decouples (at 1545) the carrier from the package interposer. Stage 12 of FIG. 14E, illustrates and describes an example of a state after the package interposer 402 is decoupled from the carrier 1400. The package interposer 402 may be detached from the carrier 1400. Stage 12 of FIG. 14E may illustrate a package 500.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Sequence for Fabricating a Metallization Portion

In some implementations, fabricating a substrate includes several processes. FIGS. 16A-16B illustrate an exemplary sequence for providing or fabricating a metallization portion. In some implementations, the sequence of FIGS. 16A-16B may be used to provide or fabricate the metallization portion 120. However, the process of FIGS. 16A-16B may be used to fabricate any of the metallization portions described in the disclosure.

It should be noted that the sequence of FIGS. 16A-16B may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure.

Stage 1, as shown in FIG. 16A, illustrates a state after a carrier 1600 is provided. A seed layer 1601 may be located over the carrier 1600. The carrier 1600 may be replaced with other components and/or materials.

Stage 2 illustrates a state after a plurality of interconnects 1612 are formed. The interconnects 1612 may be located over the seed layer 1601. A lithography process, a plating process, a strip process and/or an etching process may be used to form the plurality of interconnects 1612. The interconnects 1612 may represent at least some of the interconnects from the plurality of metallization interconnects 123.

Stage 3 illustrates a state after a dielectric layer 1610 is formed over the carrier 1600, the seed layer 1601 and the plurality of interconnects 1612. A deposition and/or lamination process may be used to form the dielectric layer 1610. The dielectric layer 1610 may include prepreg and/or polyimide. The dielectric layer 1610 may include a photo-imageable dielectric. However, different implementations may use different materials for the dielectric layer.

Stage 4 illustrates a state after a plurality of cavities 1613 is formed in the dielectric layer 1610. The plurality of cavities 1613 may be formed using an etching process (e.g., photo etching process), a laser process, an exposure process and/or a development process.

Stage 5 illustrates a state after interconnects 1622 are formed in and over the dielectric layer 1610, including in and over the plurality of cavities 1613. For example, a via, pad and/or traces may be formed. A lithography process, a plating process, a strip process and/or an etching process may be used to form the interconnects.

Stage 6, as shown in FIG. 16B, illustrates a state after a dielectric layer 1620 is formed over the dielectric layer 1610 and the plurality of interconnects 1622. A deposition and/or lamination process may be used to form the dielectric layer 1620. The dielectric layer 1620 may include prepreg and/or polyimide. The dielectric layer 1620 may include a photo-imageable dielectric. However, different implementations may use different materials for the dielectric layer.

Stage 7, illustrates a state after a plurality of cavities 1623 is formed in the dielectric layer 122. The dielectric layer 122 may represent the dielectric layer 1610 and/or the dielectric layer 1620. The plurality of cavities 1623 may be formed using an etching process (e.g., photo etching process), a laser process, an exposure process and/or a development process.

Stage 8 illustrates a state after interconnects 1632 are formed in and over the dielectric layer 142, including in and over the plurality of cavities 1623. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Metallization Portion

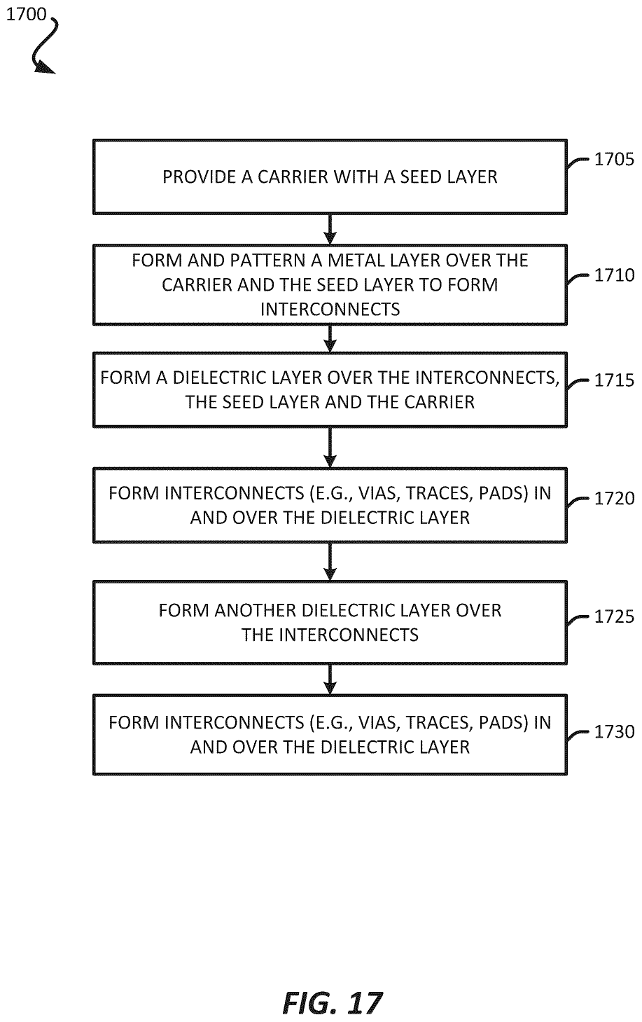

In some implementations, fabricating a substrate includes several processes. FIG. 17 illustrates an exemplary flow diagram of a method 1700 for providing or fabricating a metallization portion. In some implementations, the method 1700 of FIG. 17 may be used to provide or fabricate the metallization portion(s) of the disclosure. For example, the method 1700 of FIG. 17 may be used to fabricate the metallization portion 120.

It should be noted that the method 1700 of FIG. 17 may combine one or more processes in order to simplify and/or clarify the method for providing or fabricating a metallization portion. In some implementations, the order of the processes may be changed or modified.

The method provides (at 1705) a carrier with a seed layer. Stage 1 of FIG. 16A, illustrates and describes an example of a state after a carrier 1600 is provided. A seed layer 1601 may be located over the carrier 1600. The carrier 1600 may be replaced with other components and/or materials.

The method forms and patterns (at 1710) a plurality of interconnects. Stage 2 of FIG. 16A, illustrates and describes an example of a state after a plurality of interconnects 1612 are formed. The interconnects 1612 may be located over the seed layer 1601. A lithography process, a plating process, a strip process and/or an etching process may be used to form the plurality of interconnects 1612. The interconnects 1612 may represent at least some of the interconnects from the plurality of metallization interconnects 123.

The method forms (at 1710) a dielectric layer. Stage 3 of FIG. 16A, illustrates and describes an example of a state after a dielectric layer 1610 is formed over the carrier 1600, the seed layer 1601 and the plurality of interconnects 1612. A deposition and/or lamination process may be used to form the dielectric layer 1610. The dielectric layer 1610 may include prepreg and/or polyimide. The dielectric layer 1610 may include a photo-imageable dielectric. However, different implementations may use different materials for the dielectric layer.

The method forms (at 1720) a plurality of interconnects. Forming a plurality of interconnects may including forming a plurality of cavities in a dielectric layer and a performing a plating process. Stage 4 of FIG. 16A, illustrates and describes an example of a state after a plurality of cavities 1613 is formed in the dielectric layer 1610. The plurality of cavities 1613 may be formed using an etching process (e.g., photo etching process), a laser process, an exposure process and/or a development process.

Stage 5 of FIG. 16A, illustrates and describes an example of a state after interconnects 1622 are formed in and over the dielectric layer 1610, including in and over the plurality of cavities 1613. For example, a via, pad and/or traces may be formed. A lithography process, a plating process, a strip process and/or an etching process may be used to form the interconnects.

The method forms (at 1725) another dielectric layer. Stage 6 of FIG. 16B, illustrates and describes an example of a state after a dielectric layer 1620 is formed over the dielectric layer 1610 and the plurality of interconnects 1622. A deposition and/or lamination process may be used to form the dielectric layer 1620. The dielectric layer 1620 may include prepreg and/or polyimide. The dielectric layer 1620 may include a photo-imageable dielectric. However, different implementations may use different materials for the dielectric layer.

The method forms (at 1730) a plurality of interconnects. Forming a plurality of interconnects may including forming a plurality of cavities in a dielectric layer and a performing a plating process. Stage 7 of FIG. 16B, illustrates and describes an example of a state after a plurality of cavities 1623 is formed in the dielectric layer 142. The dielectric layer 142 may represent the dielectric layer 1610 and/or the dielectric layer 1620. The plurality of cavities 1623 may be formed using an etching process (e.g., photo etching process), a laser process, an exposure process and/or a development process.

Stage 8 of FIG. 16B, illustrates and describes an example of a state after interconnects 1632 are formed in and over the dielectric layer 122, including in and over the plurality of cavities 1623. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

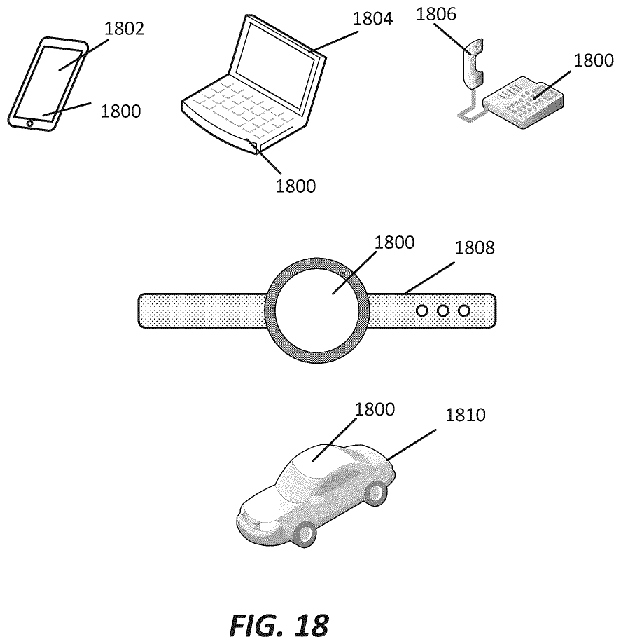

FIG. 18 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 1802, a laptop computer device 1804, a fixed location terminal device 1806, a wearable device 1808, or automotive vehicle 1810 may include a device 1800 as described herein. The device 1800 may be, for example, any of the devices and/or integrated circuit (IC) packages described herein. The devices 1802, 1804, 1806 and 1808 and the vehicle 1810 illustrated in FIG. 18 are merely exemplary. Other electronic devices may also feature the device 1800 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-11, 12A-12E, 13, 14A-14E, 15, 16A-16B, and 17-18 may be rearranged and/or combined into a single component, process, feature or function or embodied in several components, processes, or functions. Additional elements, components, processes, and/or functions may also be added without departing from the disclosure. It should also be noted FIGS. 1-11, 12A-12E, 13, 14A-14E, 15, 16A-16B, and 17-18 and its corresponding description in the present disclosure is not limited to dies and/or ICs. In some implementations, FIGS. 1-11, 12A-12E, 13, 14A-14E, 15, 16A-16B, and 17-18 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. A seed layer may be considered part of an interconnect. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.
Aspect 1: A package comprising a first integrated device; a second integrated device; and a package interposer coupled to the first integrated device and the second integrated device. The package interposer comprises a first metallization portion; a second metallization portion; a first encapsulation layer coupled to the first metallization portion and the second metallization portion; and a passive device located at least partially in the first encapsulation layer. The first encapsulation layer and the passive device are located between the first metallization portion and the second metallization portion.
Aspect 2: The package of aspect 1, wherein the passive device comprises a trench capacitor device.
Aspect 3: The package of aspect 2, wherein the trench capacitor device comprises at least one through substrate via.
Aspect 4: The package of aspects 1 through 3, wherein the passive device is coupled to the first metallization portion through a plurality of solder interconnects.
Aspect 5: The package of aspects 1 through 3, wherein the passive device is coupled to the second metallization portion through a plurality of solder interconnects.
Aspect 6: The package of aspects 1 through 5, wherein the first integrated device is coupled to the package interposer through a first plurality of solder interconnects; and wherein the second integrated device is coupled to the package interposer through a second plurality of solder interconnects.
Aspect 7: The package of aspects 1 through 6, further comprising a second encapsulation layer coupled to the package interposer, the first integrated device and the second integrated device.
Aspect 8: The package of aspects 1 through 7, wherein the package interposer further comprises a bridge located at least partially in the first encapsulation layer.
Aspect 9: The package of aspect 8, wherein the first integrated device is configured to be electrically coupled to the second integrated device through at least the first metallization portion and the bridge.
Aspect 10: The package of aspect 8, wherein the first integrated device is configured to be electrically coupled to the second integrated device through at least the second metallization portion and the bridge.
Aspect 11: The package of aspect 8, wherein the bridge is coupled to the second metallization portion through a plurality of solder interconnects.
Aspect 12: The package of aspects 1 through 11, wherein an electrical path between the first metallization portion and the second metallization portion includes the passive device.
Aspect 13: The package of aspects 1 through 12, further comprising a plurality of post interconnects located at least partially in the first encapsulation layer, wherein the plurality of post interconnects is coupled to the first metallization portion and the second metallization portion.
Aspect 14: The package of aspects 1 through 13, wherein the first metallization portion comprises at least one first dielectric layer; and a first plurality of metallization interconnects, and wherein the second metallization portion comprises at least one second dielectric layer; and a second plurality of metallization interconnects.
Aspect 15: The package of aspects 1 through 14, wherein the first integrated device includes a system on chip, and wherein the second integrated device includes memory device.
Aspect 16: A device comprising a package. The package comprises a first integrated device; a second integrated device; and a package interposer coupled to the first integrated device and the second integrated device. The package interposer comprises a first metallization portion; a second metallization portion; a first encapsulation layer coupled to the first metallization portion and the second metallization portion; and a passive device located at least partially in the first encapsulation layer, wherein the first encapsulation layer and the passive device are located between the first metallization portion and the second metallization portion.
Aspect 17: The device of aspect 16, further comprising a laminated substrate coupled to the package.
Aspect 18: The device of aspect 16, further comprising a board coupled to the package.
Aspect 19: The device of aspects 16 through 18, wherein the passive device comprises a trench capacitor device.
Aspect 20: The device of aspects 16 through 19, wherein the device is one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.
Aspect 21: A package comprising a first integrated device; a second integrated device; and a package interposer coupled to the first integrated device and the second integrated device. The package interposer comprises a first metallization portion; a second metallization portion; a first encapsulation layer coupled to the first metallization portion and the second metallization portion; and a bridge located at least partially in the first encapsulation layer, wherein the first encapsulation layer and the bridge are located between the first metallization portion and the second metallization portion.
Aspect 22: The package of aspect 21, wherein the package interposer further comprises a trench capacitor device located at least partially in the first encapsulation layer.
Aspect 23: The package of aspect 22, wherein the trench capacitor device comprises at least one through substrate via.
Aspect 24: The package of aspects 21 through 23, wherein the first integrated device is configured to be electrically coupled to the second integrated device through at least the first metallization portion and the bridge.
Aspect 25: The package of aspects 21 through 24, wherein the first integrated device is configured to be electrically coupled to the second integrated device through at least the second metallization portion and the bridge.
Aspect 26: The package of aspects 21 through 25, wherein an electrical path between the first metallization portion and the second metallization portion includes the passive device.
Aspect 27: The package of aspects 21 through 26, wherein the bridge is coupled to the second metallization portion through a plurality of solder interconnects.
Aspect 28: The package of aspects 21 through 27, wherein the bridge is coupled to the first metallization portion through an adhesive.
Aspect 29: The package of aspects 21 through 28, further comprising a plurality of post interconnects located at least partially in the first encapsulation layer, wherein the plurality of post interconnects is coupled to the first metallization portion and the second metallization portion.
Aspect 30: The package of aspects 21 through 29, wherein the bridge is a silicon based bridge comprising a bridge substrate and a plurality of bridge interconnects.
Aspect 31: A method for fabricating a package. The method forms a first metallization portion. The method forms a plurality of post interconnects that are coupled to the first metallization portion. The method couples at least one passive device and/or at least one bridge to the first metallization portion. The method forms a first encapsulation layer that is coupled to the first metallization portion. The method forms a second metallization portion that is coupled to the encapsulated portion. The method couples a first integrated device to the second metallization portion. The method couples a second integrated device to the second metallization portion. The method forms a second encapsulation layer that is coupled to the second metallization portion, the first integrated device and the second integrated device.
Aspect 32: The method of aspect 31, wherein the first encapsulation layer and the passive device are located between the first metallization portion and the second metallization portion.
Aspect 33: The method of aspects 31 through 32, wherein the first integrated device is coupled to the second metallization portion through a first plurality of solder interconnects.
Aspect 34: The method of aspects 31 through 33, wherein the at least one passive device is coupled to the first metallization portion through a first plurality of solder interconnects.
Aspect 35: The method of aspects 31 through 33, wherein the at least one passive device and/or the at least one bridge is coupled to the first metallization portion through and adhesive.
Aspect 36: A method for fabricating a package. The method forms a first metallization portion. The method forms a plurality of post interconnects that are coupled to the first metallization portion. The method couples at least one passive device and/or at least one bridge to the first metallization portion. The method forms a first encapsulation layer that is coupled to the first metallization portion. The first encapsulation layer may at least partially encapsulate the plurality of post interconnects, the at least one passive device and/or the at least one bridge. The method forms a second metallization portion that is coupled to the encapsulation layer. The method couples a first integrated device to the second metallization portion. The method couples a second integrated device to the second metallization portion. The method forms a second encapsulation layer that is coupled to the second metallization portion, the first integrated device and the second integrated device.
Aspect 32: The method of aspect 31, wherein the first encapsulation layer, the at least one passive device and/or the at least one bridge are located between the first metallization portion and the second metallization portion.
Aspect 33: The method of aspects 31 through 32, wherein the first integrated device is coupled to the second metallization portion through a first plurality of solder interconnects.
Aspect 34: The method of aspects 31 through 33, wherein the at least one passive device is coupled to the first metallization portion through a first plurality of solder interconnects.
Aspect 35: The method of aspects 31 through 33, wherein the at least one passive device and/or the at least one bridge is coupled to the first metallization portion through an adhesive.
Aspect 36: A method for fabricating a package. The method provides a first integrated device. The method provides a second integrated device. The method forms a first encapsulation layer that at least partially encapsulates the first integrated device and the second integrated device. The method forms a first metallization portion that is coupled to the first encapsulation layer. The method forms a plurality of post interconnects that are coupled to the first metallization portion. The method couples at least one passive device and/or at least one bridge to the first metallization portion. The method forms a second encapsulation layer that is coupled to the first metallization portion, where the second encapsulation layer at least partially encapsulate the plurality of post interconnects, the at least one passive device and/or the at least one bridge. The method forms a second metallization portion that is coupled to the encapsulation layer.
Aspect 37: The method of aspect 36, wherein the second encapsulation layer, the at least one passive device and/or the at least one bridge are located between the first metallization portion and the second metallization portion.
Aspect 38: The method of aspects 31 through 33, wherein the at least one passive device and/or the at least one bridge is coupled to the first metallization portion through a plurality of solder interconnects.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a first integrated device;
a second integrated device; and
a package interposer coupled to the first integrated device and the second integrated device, the package interposer comprising:
a first metallization portion;
a second metallization portion;
a first encapsulation layer coupled to the first metallization portion and the second metallization portion; and
a passive device located at least partially in the first encapsulation layer,
wherein the first encapsulation layer and the passive device are located between the first metallization portion and the second metallization portion.

2. The package of claim 1, wherein the passive device comprises a trench capacitor device.

3. The package of claim 2, wherein the trench capacitor device comprises at least one through substrate via.

4. The package of claim 1, wherein the passive device is coupled to the first metallization portion through a plurality of solder interconnects.

5. The package of claim 1, wherein the passive device is coupled to the second metallization portion through a plurality of solder interconnects.

6. The package of claim 1,
wherein the first integrated device is coupled to the package interposer through a first plurality of solder interconnects; and
wherein the second integrated device is coupled to the package interposer through a second plurality of solder interconnects.

7. The package of claim 1, further comprising a second encapsulation layer coupled to the package interposer, the first integrated device and the second integrated device.

8. The package of claim 1, wherein the package interposer further comprises a bridge located at least partially in the first encapsulation layer.

9. The package of claim 8, wherein the first integrated device is configured to be electrically coupled to the second integrated device through at least the first metallization portion and the bridge.

10. The package of claim 8, wherein the first integrated device is configured to be electrically coupled to the second integrated device through at least the second metallization portion and the bridge.

11. The package of claim 8, wherein the bridge is coupled to the second metallization portion through a plurality of solder interconnects.

12. The package of claim 1, wherein an electrical path between the first metallization portion and the second metallization portion includes the passive device.

13. The package of claim 1, further comprising a plurality of post interconnects located at least partially in the first encapsulation layer, wherein the plurality of post interconnects is coupled to the first metallization portion and the second metallization portion.

14. The package of claim 1,
wherein the first metallization portion comprises:
at least one first dielectric layer; and
a first plurality of metallization interconnects, and
wherein the second metallization portion comprises:
at least one second dielectric layer; and
a second plurality of metallization interconnects.

15. The package of claim 1,
wherein the first integrated device includes a system on chip, and
wherein the second integrated device includes memory device.

16. A device comprising:
a package comprising:
a first integrated device;
a second integrated device; and
a package interposer coupled to the first integrated device and the second integrated device, the package interposer comprising:
a first metallization portion;
a second metallization portion;
a first encapsulation layer coupled to the first metallization portion and the second metallization portion; and
a passive device located at least partially in the first encapsulation layer,
wherein the first encapsulation layer and the passive device are located between the first metallization portion and the second metallization portion.

17. The device of claim 16, further comprising a laminated substrate coupled to the package.

18. The device of claim 16, further comprising a board coupled to the package.

19. The device of claim 16, wherein the passive device comprises a trench capacitor device.

20. The device of claim 16, wherein the device is one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.
